(19) United States
(12) Patent Application Publication
(10) Pub. No.: US 2024/0040814 A1
(43) Pub. Date: Feb. 1, 2024

(54) Organic Light-Emitting Diode Device

(71) Applicant: JAPAN SCIENCE AND TECHNOLOGY AGENCY, Saitama (JP)

(72) Inventors: Seiichiro Izawa, Yokohama-shi (JP); Masahiro Hiramoto, Okazaki-shi (JP); Masahiro Morimoto, Toyama-shi (JP); Shigeki Naka, Toyama-shi (JP)

(73) Assignee: JAPAN SCIENCE AND TECHNOLOGY AGENCY, Saitama (JP)

(21) Appl. No.: 18/374,629

(22) Filed: Sep. 28, 2023

Related U.S. Application Data
(63) Continuation of application No. PCT/JP2022/016598, filed on Mar. 31, 2022.

(30) Foreign Application Priority Data
Apr. 1, 2021 (JP) 2021-062767

(51) Int. Cl. H10K 50/12

(52) U.S. Cl. CPC H10K 50/12; H10K 2101/40

(57) ABSTRACT

Provided is an OLED device 10 including a plurality of organic semiconductor layers sandwiched between a pair of electrodes 3 and 4. The organic semiconductor layers include a first organic semiconductor layer 1 containing a first organic semiconductor material, and a second organic semiconductor layer 2 containing a second organic semiconductor material and a third organic semiconductor material, the first organic semiconductor layer and the second organic semiconductor layer form a joining surface, and the first organic semiconductor material and the second organic semiconductor material satisfy requirement and the like relating to a predetermined energy level.

### TECHNICAL FIELD

The present invention relates to an OLED device.

### BACKGROUND ART

An OLED (organic light-emitting diode) device is an element that includes one or two or more organic semiconductor layers sandwiched between a pair of electrodes, and emits light by itself when applying voltage between the electrodes.

In recent years, a research has been actively conducted to increase light-emission efficiency and light-emission luminance of an OLED device. For example, an energy up-converted OLED device that has a structure in which a rubrene layer and a C60 layer are stacked in this order is proposed in Non-Patent Literature 1.

### CITATION LIST

### Non Patent Literature

Non Patent Literature 1: Ajay K. Pandey, Scientific Reports 2015, 5, 7787.

### SUMMARY OF INVENTION

### Technical Problem

Incidentally, as a result of an examination conducted by the present inventors, it has become clear that there is room for improvement in light-emission efficiency and light-emission luminance with respect to the OLED device in the related art such as Non-Patent Literature 1.

An object of the invention is to provide an OLED device excellent in light-emission efficiency and light-emission luminance.

### Solution to Problem

The present inventors have conducted a thorough examination in consideration of the above-described circumstances, and as a result thereof, they found an OLED device having the following configuration.

That is, an OLED device of the invention is,

an OLED device including a plurality of organic semiconductor layers sandwiched between a pair of electrodes.

The organic semiconductor layers include a first organic semiconductor layer containing a first organic semiconductor material, and a second organic semiconductor layer containing a second organic semiconductor material and a third organic semiconductor material.

The first organic semiconductor layer and the second organic semiconductor layer form a joining surface.

A HOMO level of the first organic semiconductor material is lower than a HOMO level of the second organic semiconductor material, and a LUMO level of the first organic semiconductor material is lower than a LUMO level of the second organic semiconductor material.

The second organic semiconductor material is a material in which triplet-triplet annihilation is caused to occur.

An energy of a first triplet excited state (T₁) of the second organic semiconductor material is smaller than an energy difference between the HOMO level of the second organic semiconductor material and the LUMO level of the first organic semiconductor material.

The energy difference between the HOMO level of the second organic semiconductor material and the LUMO level of the first organic semiconductor material is smaller than an energy difference between the HOMO level and the LUMO level of the second organic semiconductor material by 0.5 eV or more.

In the second organic semiconductor layer, the second organic semiconductor material is a host material, and the third organic semiconductor material is a dopant.

A peak wavelength of a photoluminescence spectrum of the second organic semiconductor material is on a long wavelength side in comparison to a peak wavelength of an absorption spectrum of the first organic semiconductor material.

According to the OLED device, light-emission efficiency and light-emission luminance are excellent. The reason for this is not clear, but consideration made by the present inventors will be described with reference to FIGS. 1 to 3.

FIG. 1 is a conceptual diagram illustrating a mechanism in which light-emission is caused to occur by an OLED device of the invention. In FIG. 1, an OLED device 10 includes a first organic semiconductor layer 1, a second organic semiconductor layer 2 that forms an interface (joining surface) with the first organic semiconductor layer 1, a first electrode 3 formed on a first organic semiconductor layer 1 side, and a second electrode 4 formed on a second organic semiconductor layer 2 side. In explanation stated here, respectively, the first organic semiconductor layer 1 corresponds to an electron transport layer, the second organic semiconductor layer 2 corresponds to a light-emitting layer, the first electrode 3 corresponds to a negative electrode, and the second electrode 4 corresponds to a positive electrode as in a case of Examples.

When an electron (−) is injected to the OLED device 10 from the negative electrode, and a hole (+) is injected to the OLED device 10 from the positive electrode, an electron (−)/hole (+) pair forms a charge transfer (CT) state at a joining surface of the first organic semiconductor layer 1 and the second organic semiconductor layer 2. A first triplet excited state (T₁) of a second organic semiconductor material (host material) is generated in the second organic semiconductor layer 2 by charge recombination of the CT state. A high-energy excited state (Si) is generated by causing triplet-triplet annihilation (TTA) to occur in the second organic semiconductor layer 2. When energy transfer from the second organic semiconductor material to a third organic semiconductor material (dopant) occurs in the second organic semiconductor layer 2, light-emission derived from the third organic semiconductor material occurs.

FIG. 2 is a view illustrating energy levels of rubrene, PTCDI-C8, and C60 which are used in Examples. Respectively, PTCDI-C8 and C60 correspond to the first organic semiconductor material, and rubrene corresponds to the second organic semiconductor material. A HOMO level of the first organic semiconductor material is lower than a HOMO level of the second organic semiconductor material, a LUMO level of the first organic semiconductor material is lower than a LUMO level of the second organic semiconductor material, and an energy difference between the HOMO level of the second organic semiconductor material and the LUMO level of the first organic semiconductor material is smaller than an energy difference between the HOMO level and the LUMO level of the second organic semiconductor material by 0.5 eV or more. Accordingly, it is considered that the electron (−)/hole (+) pair injected from the electrodes can form the CT state at the joining surface between the first organic semiconductor layer 1 and the second organic semiconductor layer 2.

FIG. 3 is a schematic view illustrating an energy transfer mechanism up to light-emission by OLED devices of Examples in which PTCDI-C8 is used as the first organic semiconductor material, rubrene is used as the second organic semiconductor material, and DBP is used as the third organic semiconductor material. In FIG. 3, an energy level of the CT state (CT=1.5 eV) corresponds to an energy difference between the HOMO level of the second organic semiconductor material and the LUMO level of the first organic semiconductor material, and an energy of a first triplet excited state (T₁) of the second organic semiconductor material is 1.1 eV. Since the energy of a first triplet excited state (T₁) of the second organic semiconductor material is smaller than the energy difference between the HOMO level of the second organic semiconductor material and the LUMO level of the first organic semiconductor material, it is considered that the electron (−)/hole (+) pair can generate a triplet state of the second organic semiconductor material in the second organic semiconductor layer 2 through the CT state.

Furthermore, since the peak wavelength of the photoluminescence spectrum of the second organic semiconductor material is on the long wavelength side in comparison to the peak wavelength of an absorption spectrum of the first organic semiconductor material, it is possible to suppress a light-emission luminance from being decreased due to absorption of light emitted from the OLED device by the first organic semiconductor material.

Note that, here, description has been given of a case where the first organic semiconductor layer 1 is an electron transport layer, but the first organic semiconductor layer 1 may be an electron injection layer or a hole block layer.

### Advantageous Effects of Invention

According to the OLED device of the invention, light-emission efficiency and light-emission luminance are excellent.

### BRIEF DESCRIPTION OF DRAWINGS

FIG. 1 is a conceptual diagram illustrating a mechanism in which light-emission occurs by an OLED device of the invention.

FIG. 2 is a view illustrating energy levels of rubrene, PTCDI-C8, and C60 which are used in Examples.

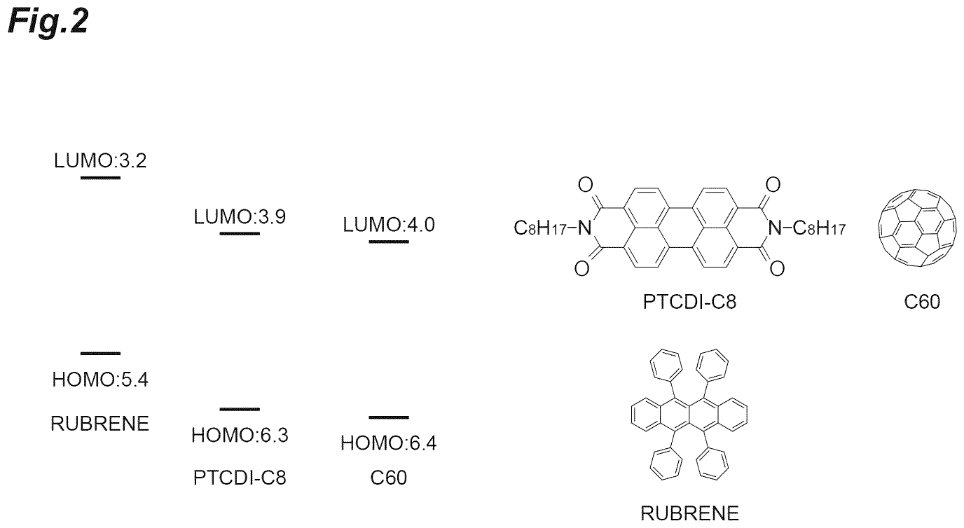

FIG. 3 is a schematic diagram illustrating an energy transfer mechanism up to light-emission by the OLED devices in Examples.

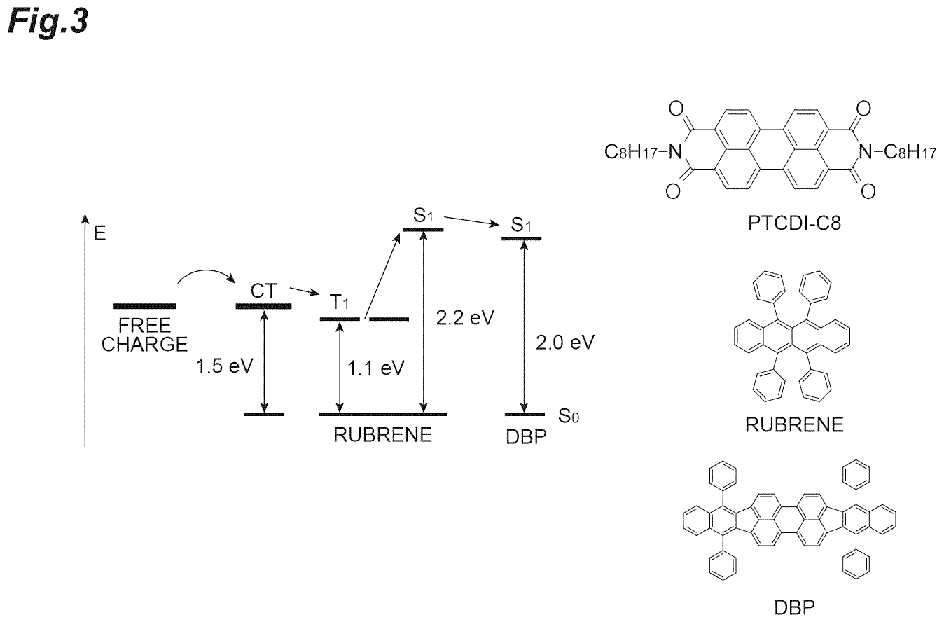

FIG. 4 is a view illustrating an absorption spectrum or a photoluminescence spectrum of compounds used in Examples.

FIG. 5 is a view illustrating a PL intensity relating to a single-layered rubrene layer.

FIG. 6(A) is a view illustrating V-luminance characteristics of OLED devices of Example 1 and the like, and FIG. 6(B) is a view illustrating external quantum yield (EQE) of the OLED devices of Example 1 and the like.

FIG. 7 is a view illustrating V-luminance characteristics of an OLED device of Example 2.

FIG. 8 is a view illustrating V-luminance characteristics of OLED devices of Example 3 and the like.

FIG. 9 is a view illustrating an external quantum yield (EQE) of OLED devices of Example 4 and the like.

FIG. 10(A) is a view illustrating an electroluminescence (EL) spectrum of OLED devices of Example 5 and the like, and FIG. 10(B) is a view illustrating V-luminance characteristics of the OLED devices of Example 5 and the like.

FIG. 11 is a view illustrating V-luminance characteristics of OLED devices of Example 6 and the like.

FIG. 12(A) is a view illustrating V-luminance characteristics of OLED devices of Example 7 and the like, and FIG. 12(B) is a view illustrating an external quantum yield (EQE) of the OLED devices of Example 7 and the like.

FIG. 13 is a view illustrating an absorption spectrum of NDI-bis-HFI.

FIG. 14 is a view illustrating V-luminance characteristics of OLED devices of Example 8 and the like.

### DESCRIPTION OF EMBODIMENTS

Hereinafter, a preferred embodiment of the invention will be described in detail. However, the invention is not limited to the following embodiment.

The OLED device of this embodiment includes a plurality of organic semiconductor layers sandwiched between a pair of electrodes. In addition, the OLED device of this embodiment may further include an inorganic compound layer such as a molybdenum trioxide (MoO₃) layer (hole injection layer) or a lithium fluoride layer (electron injection layer) between the electrodes.

The organic semiconductor layer includes a first organic semiconductor layer containing a first organic semiconductor material and a second organic semiconductor layer containing a second organic semiconductor material and a third organic semiconductor material, and the first organic semiconductor layer and the second organic semiconductor layer form a joining surface.

The first organic semiconductor layer may be formed from only the first organic semiconductor material, or may contain a material other than the first organic semiconductor material within a range that does not significantly deteriorate the effect of the invention. The second organic semiconductor layer may be formed from only the second organic semiconductor material and the third organic semiconductor material, or may contain a material other than the second and the third organic semiconductor materials within a range that does not significantly deteriorate the effect of the invention.

A HOMO level of the first organic semiconductor material is lower than a HOMO level of the second organic semiconductor material. A difference between the HOMO level of the first organic semiconductor material and the HOMO level of the second organic semiconductor material is preferably 0.5 eV or more from the viewpoint of highly preventing hole leakage to further improve light-emission efficiency. Note that, an upper limit of the difference between the HOMO level of the first organic semiconductor material and the HOMO level of the second organic semiconductor material is not particularly limited, but can be set to, for example, 2 eV or less.

A LUMO level of the first organic semiconductor material is lower than a LUMO level of the second organic semiconductor material. A difference between the LUMO level of the first organic semiconductor material and the LUMO level of the second organic semiconductor material is preferably 0.5 eV or more from the viewpoint of highly preventing electron leakage to further improve light-emission efficiency. Note that, an upper limit of the difference between the LUMO level of the first organic semiconductor material and the LUMO level of the second organic semiconductor material is not particularly limited, but can be set to, for example, 2 eV or less.

The second organic semiconductor material is a material that causes triplet-triplet annihilation to occur, and an energy of a first triplet excited state (T₁) of the second organic semiconductor material is smaller than an energy difference between the HOMO level of the second organic semiconductor material and the LUMO level of the first organic semiconductor material. A difference between the energy of a first triplet excited state (T₁) of the second organic semiconductor material and the energy difference between the HOMO level of the second organic semiconductor material and the LUMO level of the first organic semiconductor material is preferably less than 0.8 eV, more preferably less than 0.65 eV, and still more preferably less than 0.5 eV. When the difference is small, light-emission initiation voltage can be lowered.

The energy difference between the HOMO level of the second organic semiconductor material and the LUMO level of the first organic semiconductor material is smaller than an energy difference between the HOMO level and the LUMO level of the second organic semiconductor material by 0.5 eV or more, and preferably by 0.7 eV or more. An upper limit of the energy difference between the HOMO level of the second organic semiconductor material and the LUMO level of the first organic semiconductor material is not particularly limited, but can be set to, for example, 2 eV or less.

In the second organic semiconductor layer, the second organic semiconductor material is a host material, and the third organic semiconductor material is a dopant. An energy difference between a HOMO level and a LUMO level in the third organic semiconductor material is preferably smaller than the energy difference between the HOMO level and the LUMO level in the second organic semiconductor material. A peak wavelength of a photoluminescence spectrum of the third organic semiconductor material, that is the dopant, is on a long wavelength side in comparison to a peak wavelength of a photoluminescence spectrum of the second organic semiconductor material, that is the host material. When using the third organic semiconductor material, energy transfer from the second organic semiconductor material to the third organic semiconductor material occurs, and light-emission derived from the third organic semiconductor material can be realized.

The content of the third organic semiconductor material in the second organic semiconductor layer can be set to, for example, 0.01 to 50% by volume with respect to a total of 100% by volume of the second organic semiconductor layer, and preferably 0.1 to 10% by volume.

A peak wavelength of a photoluminescence spectrum of the second organic semiconductor material is on a long wavelength side in comparison to a peak wavelength of an absorption spectrum of the first organic semiconductor material. According to this, an excessive absorption loss of light-emission due to a layer other than the second organic semiconductor layer, for example, the first organic semiconductor layer can be suppressed.

As the first organic semiconductor material, for example, a known electron transport material in the related art can be employed. Specific examples thereof include the following compounds.

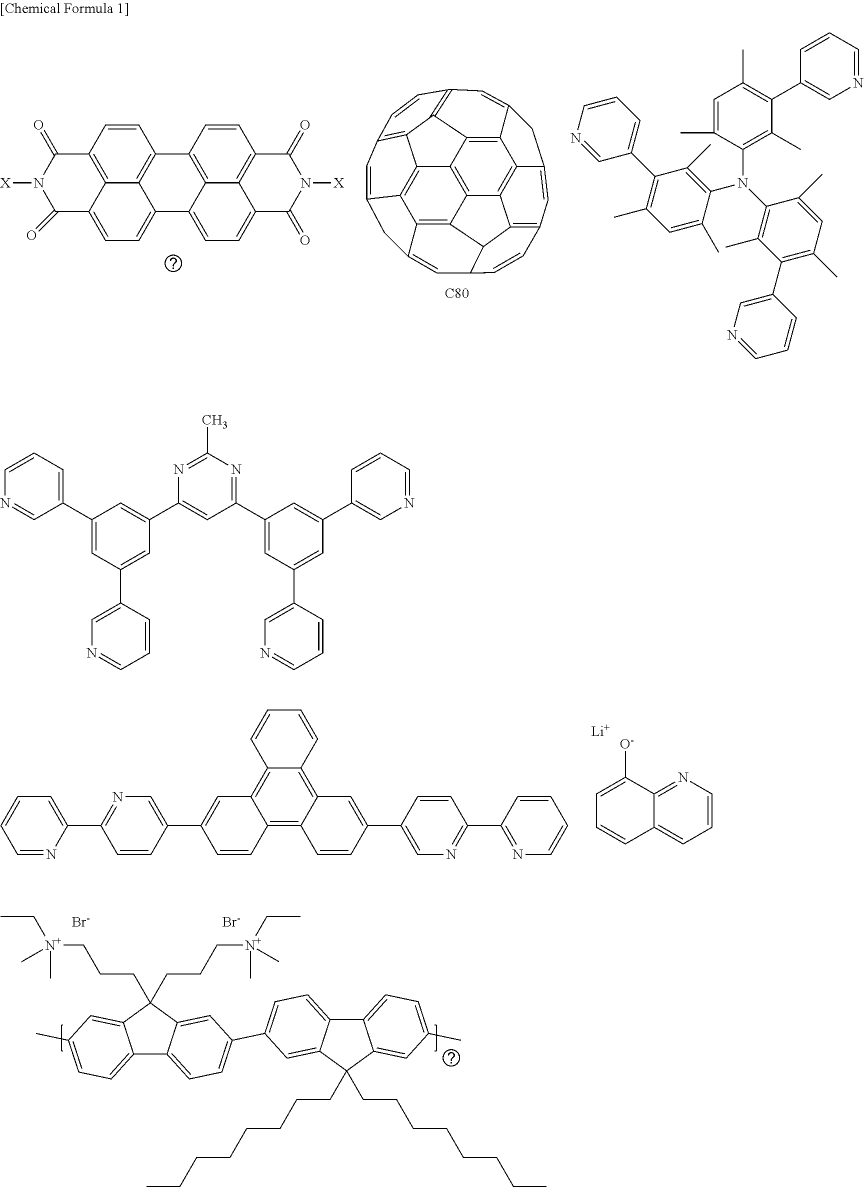

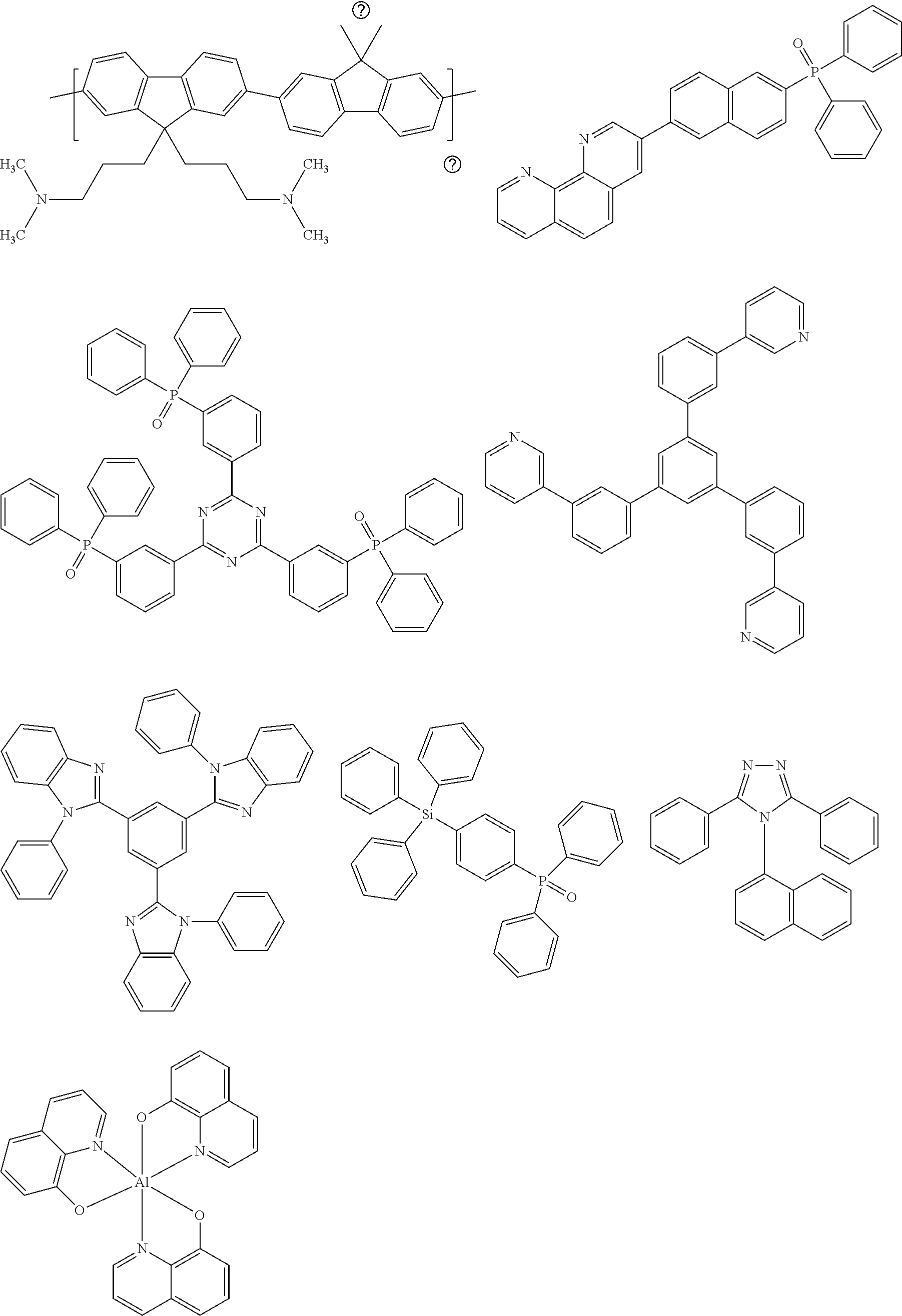

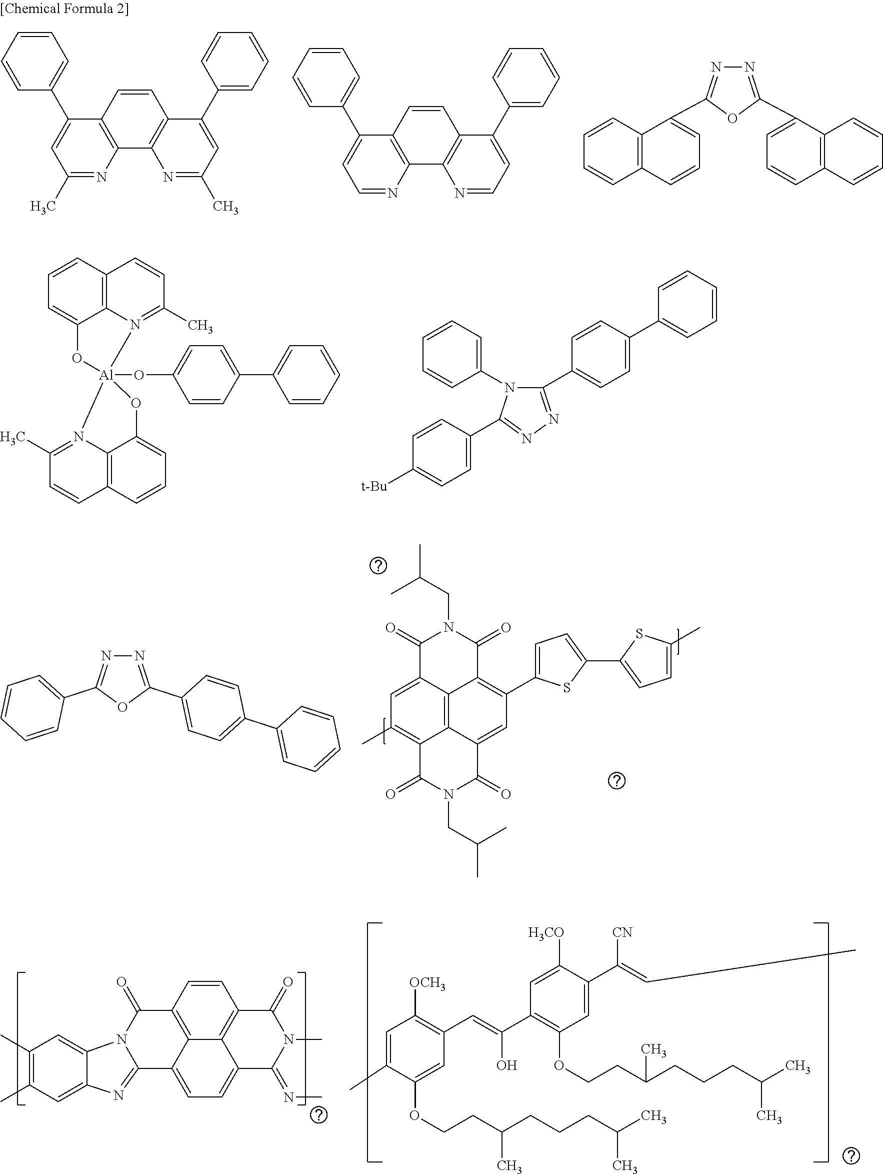

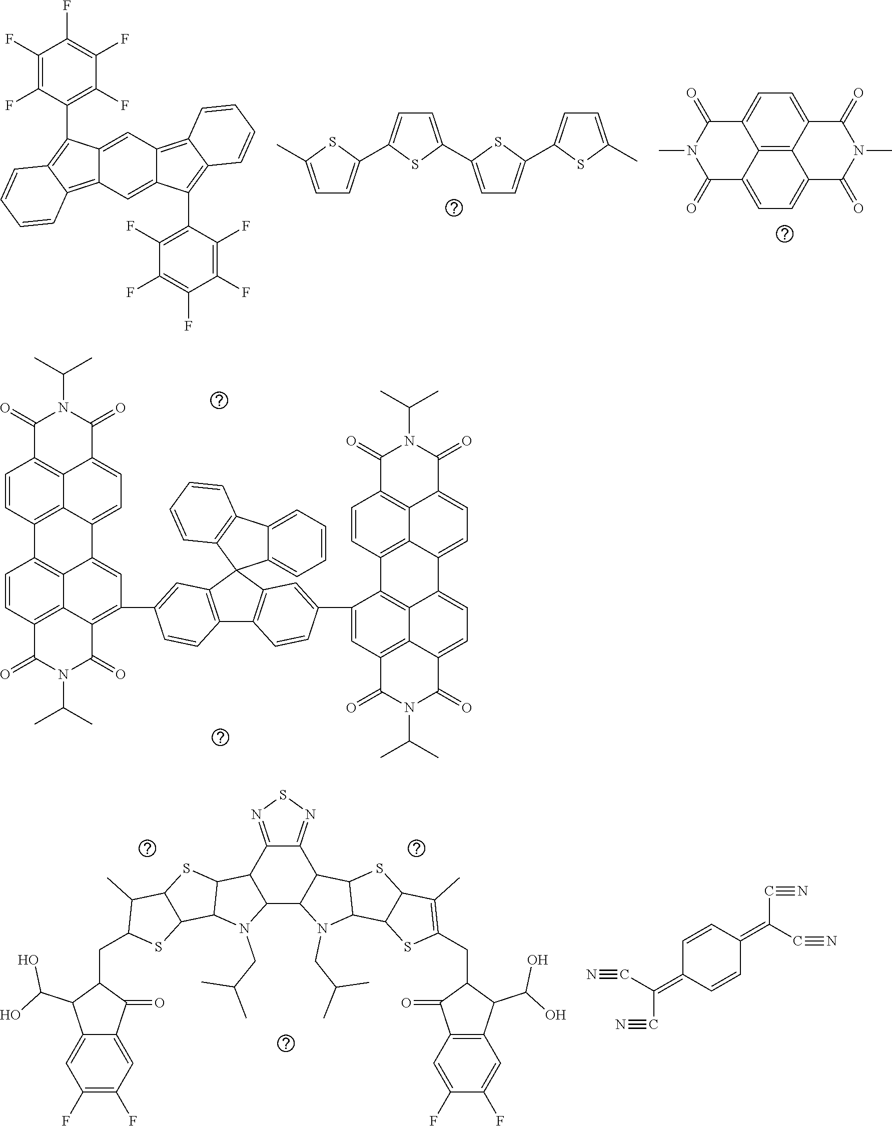

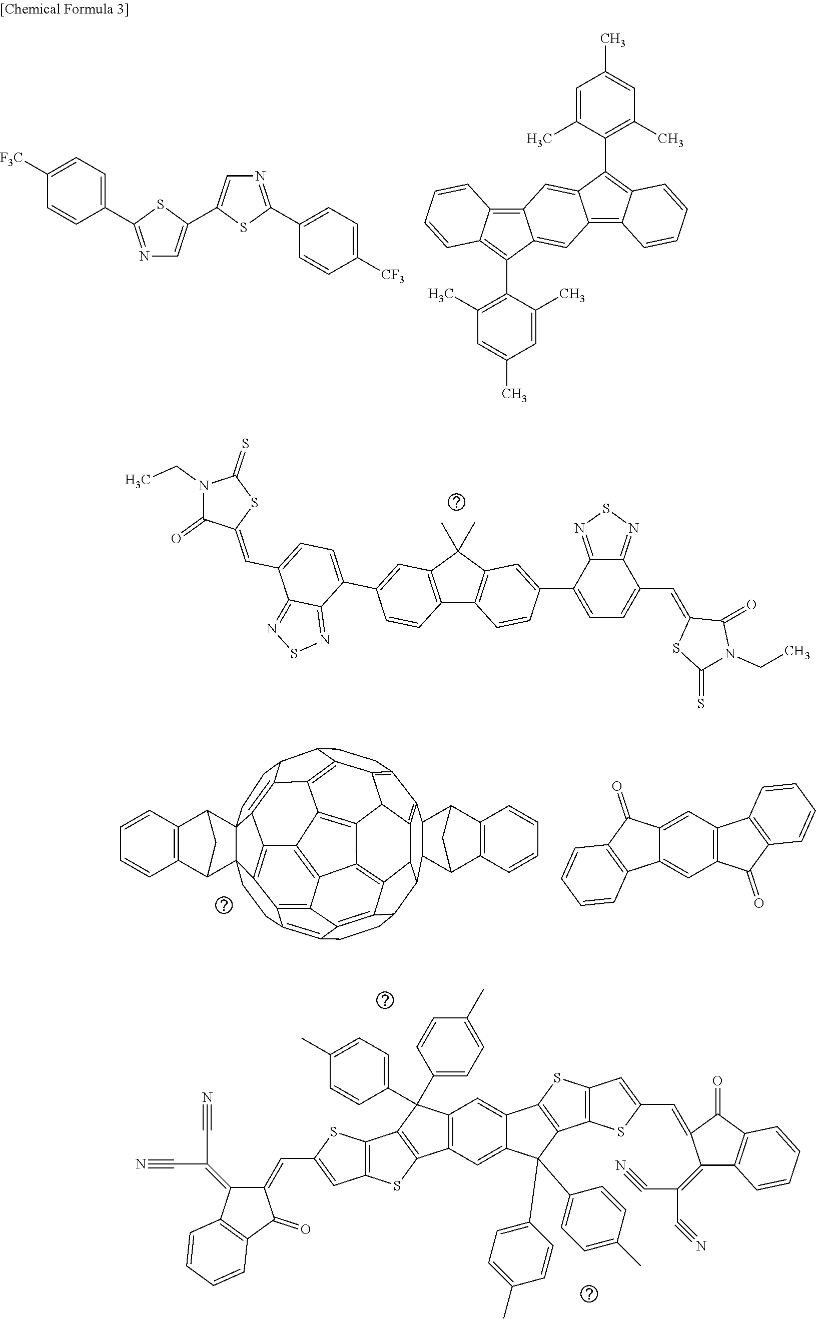

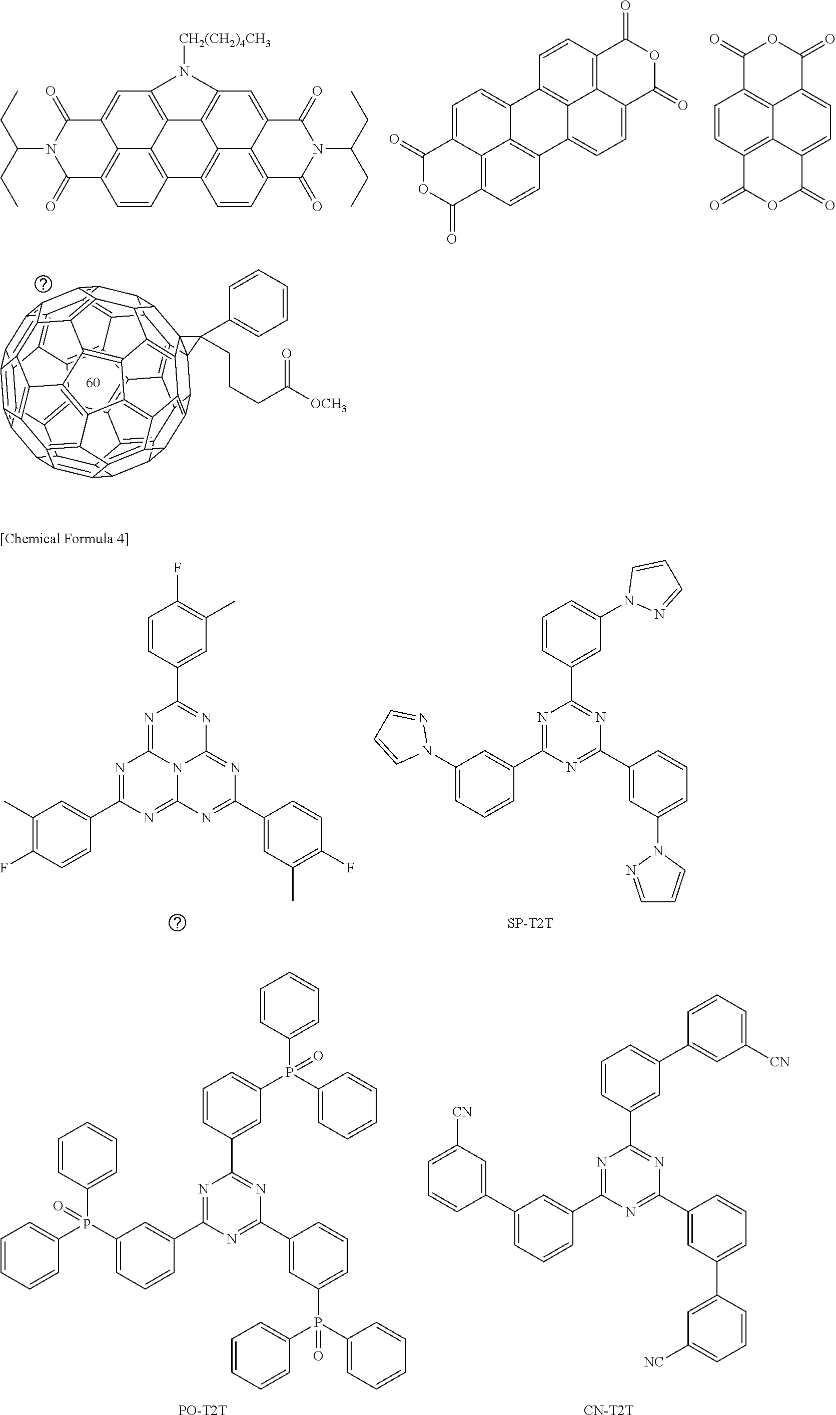

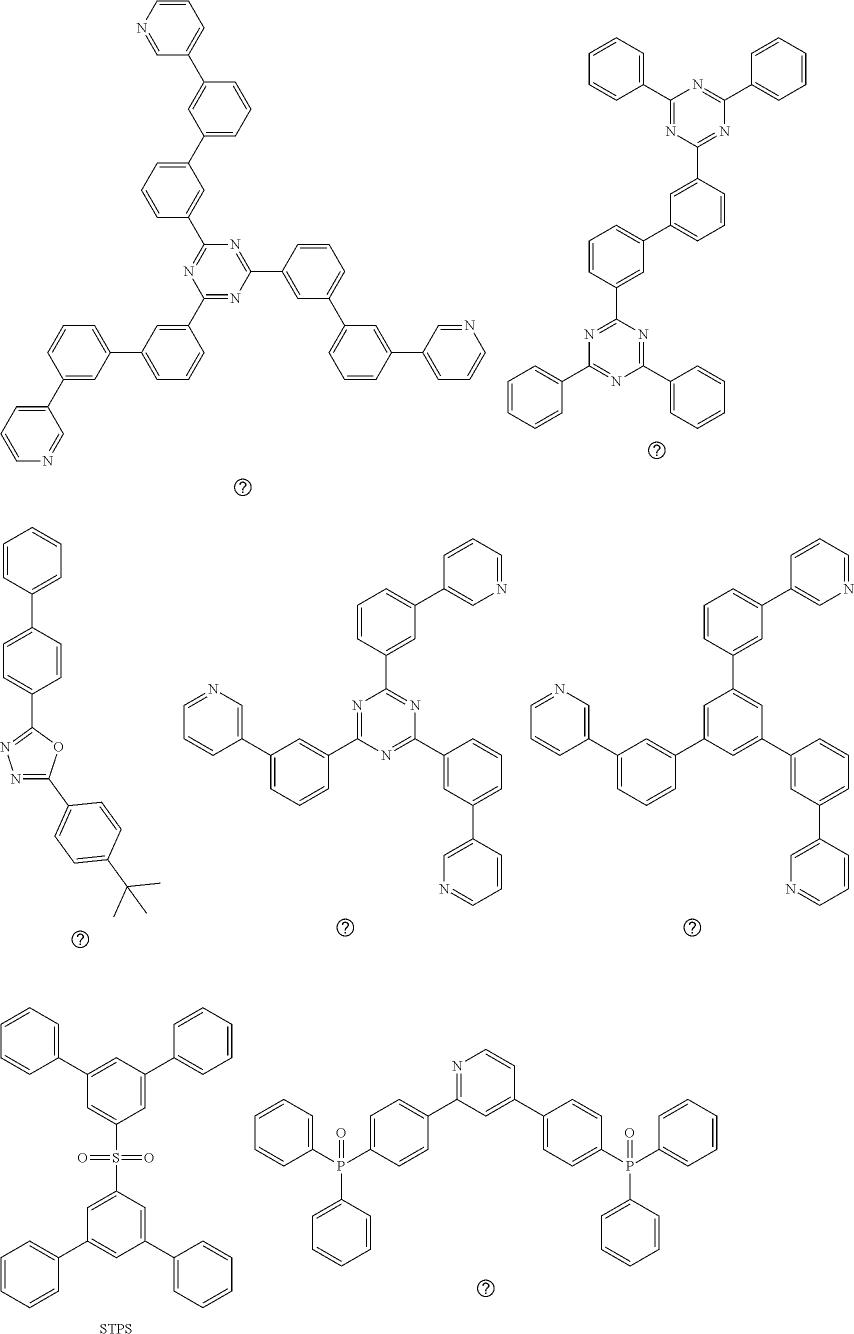

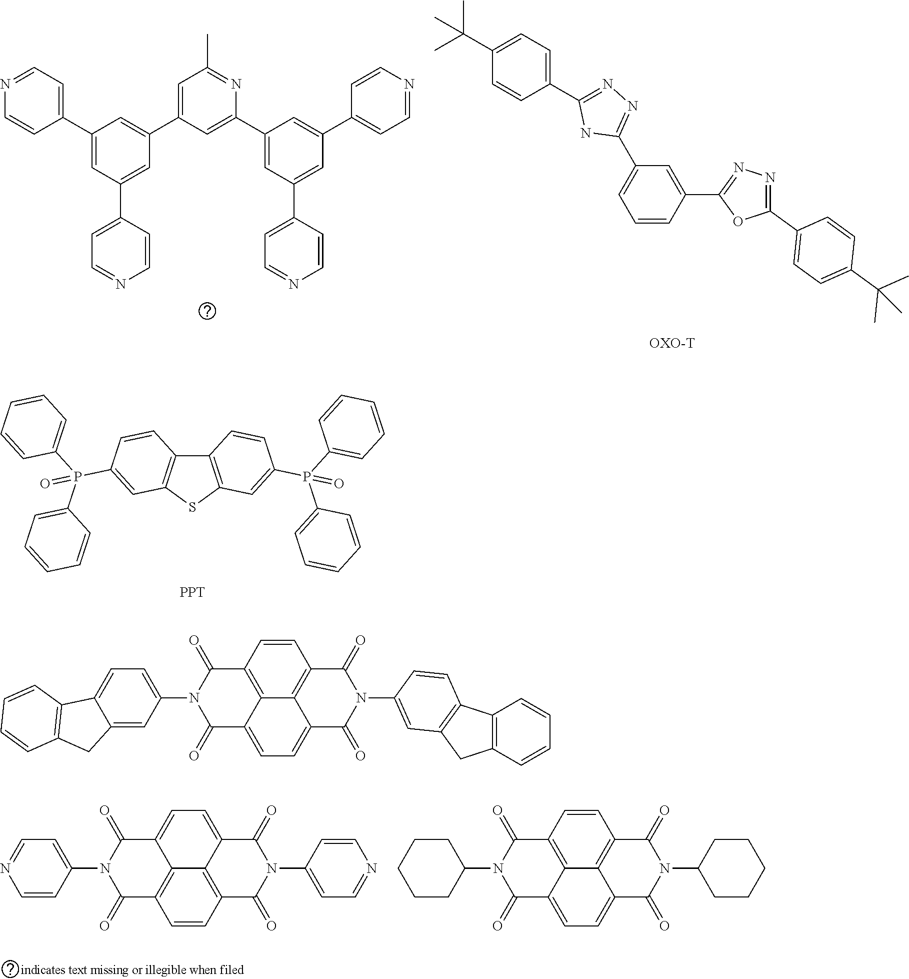

As the second organic semiconductor material, for example, the following compounds which are reported to cause TTA to occur can be employed.

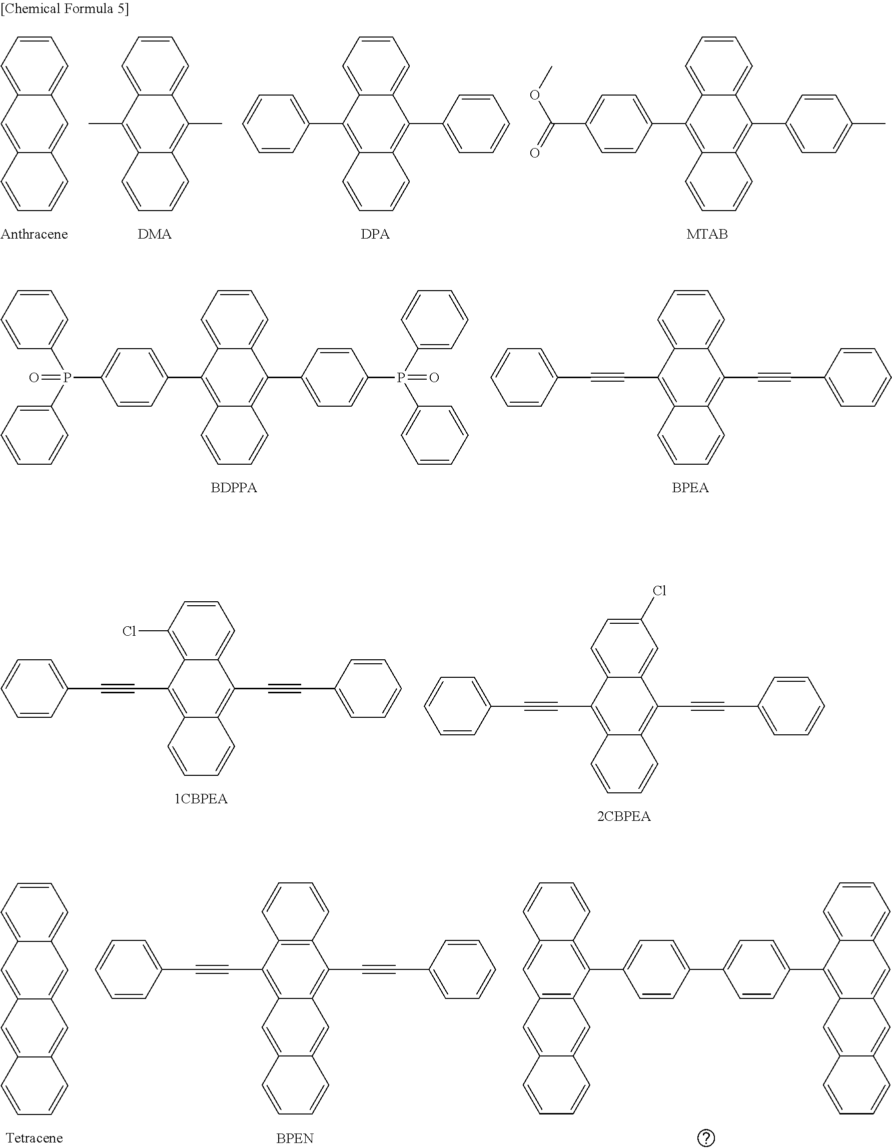

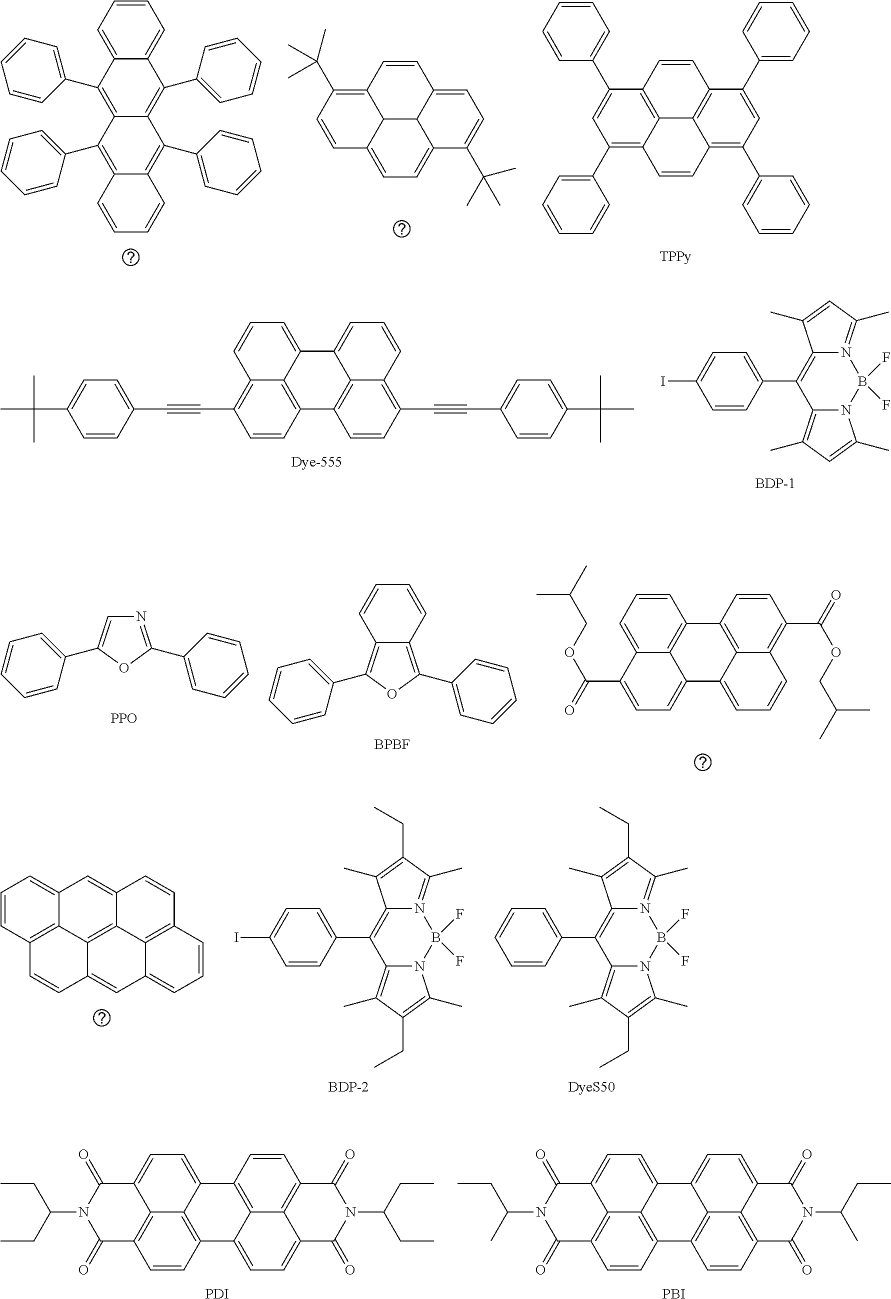

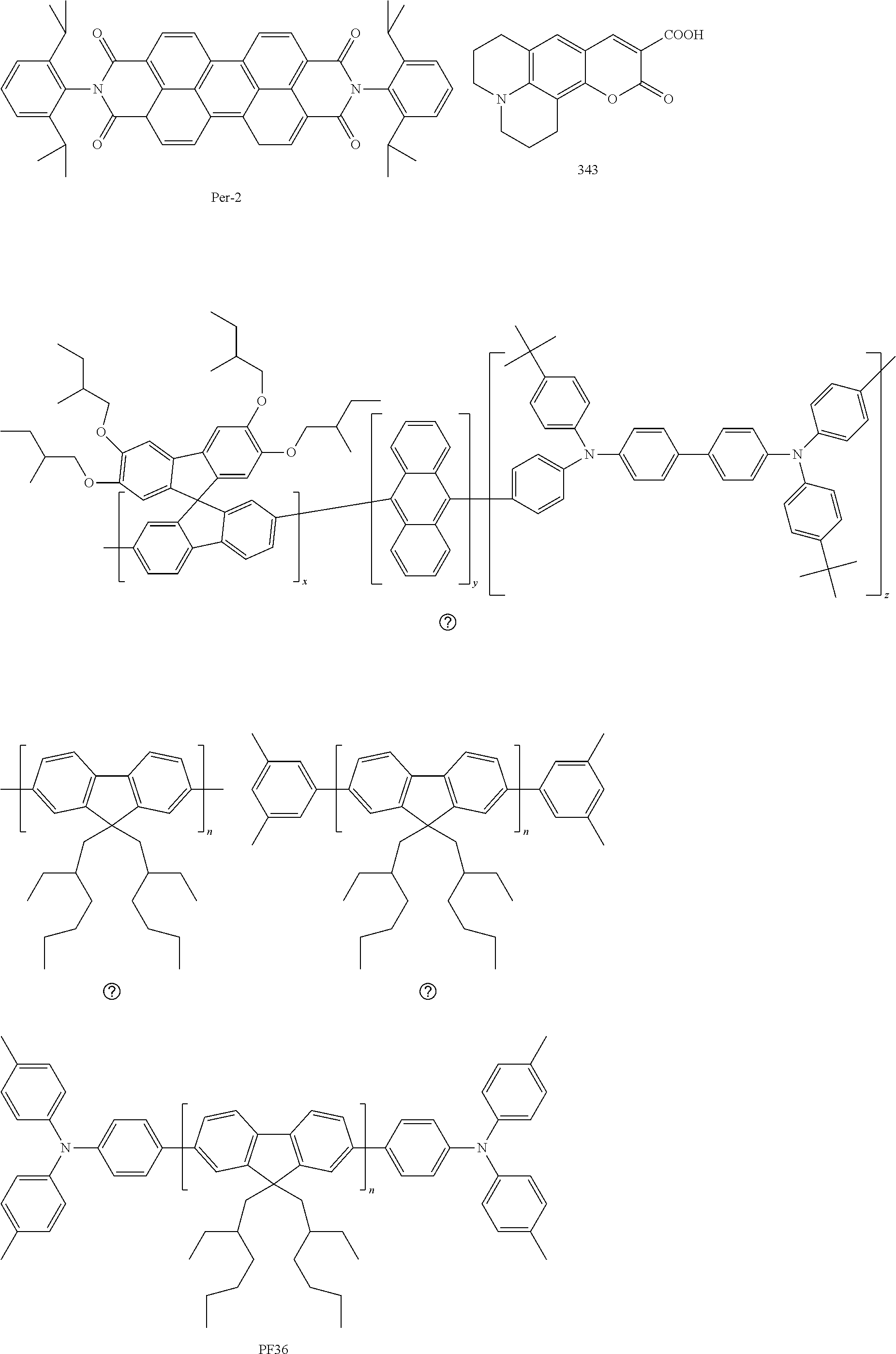

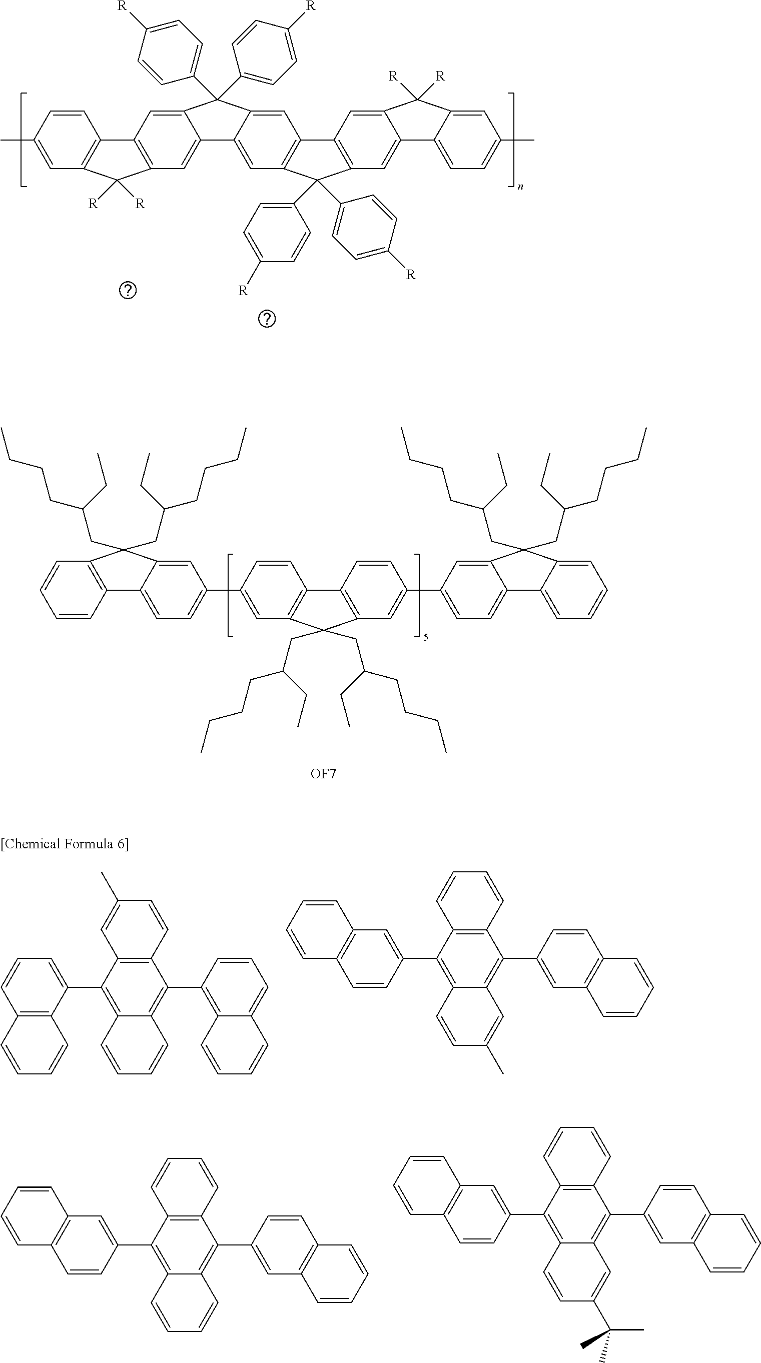

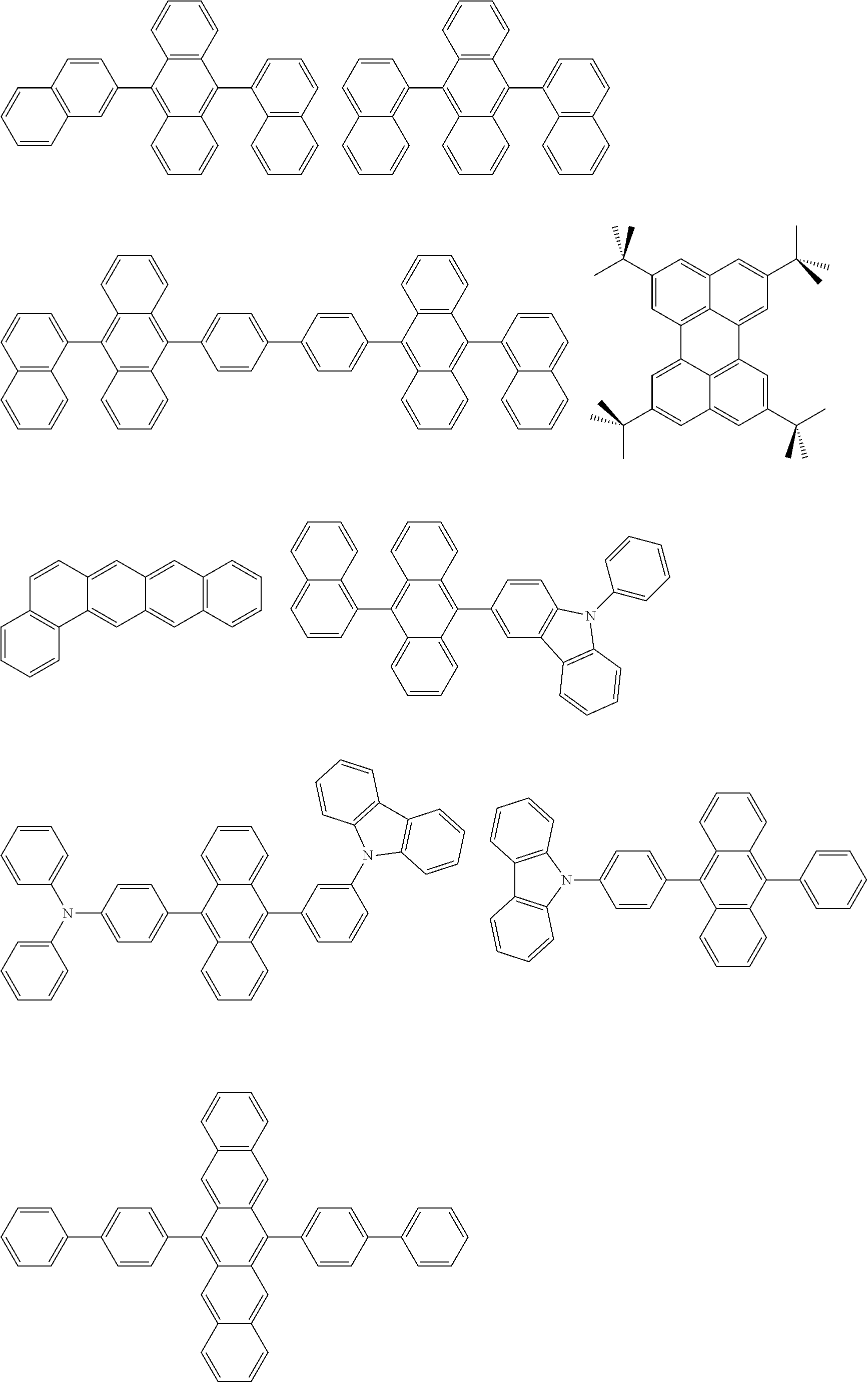

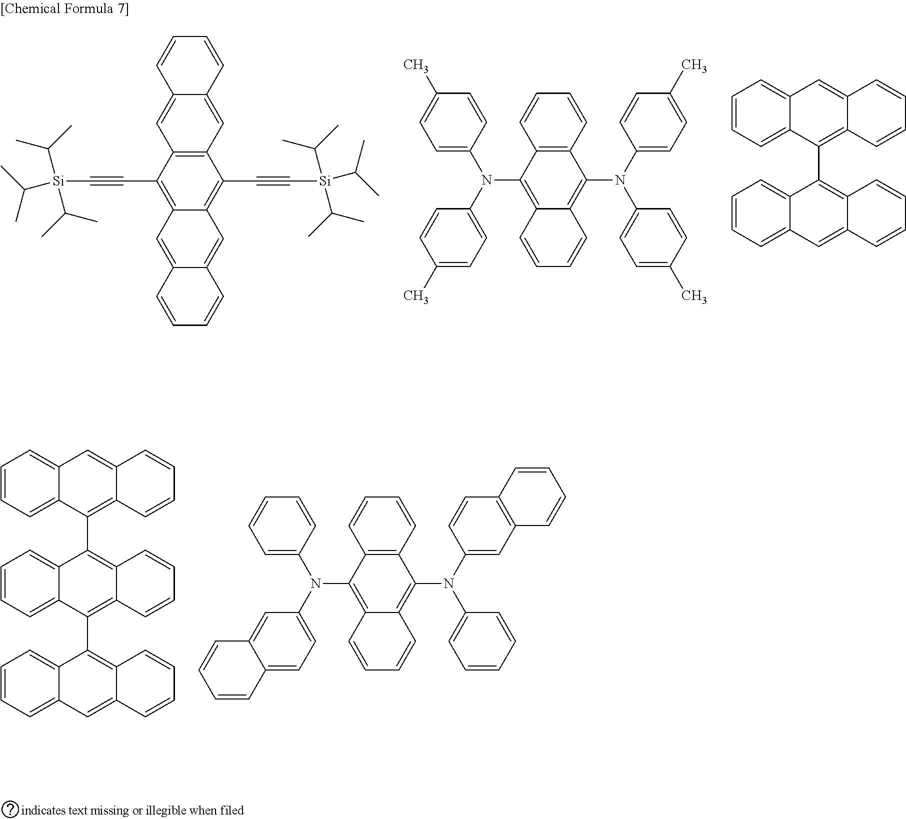

(refer to Chem. Rev. 2015, 115, 395 to 465)

Energy levels such as a HOMO level, a LUMO level, and an energy of a first triplet excited state (T₁) of the compounds are inherent to the materials, and literature values can be referred to.

As the third organic semiconductor material, a known light-emitting material in the related art can be employed. Specific examples of the third organic semiconductor material include the following compounds.

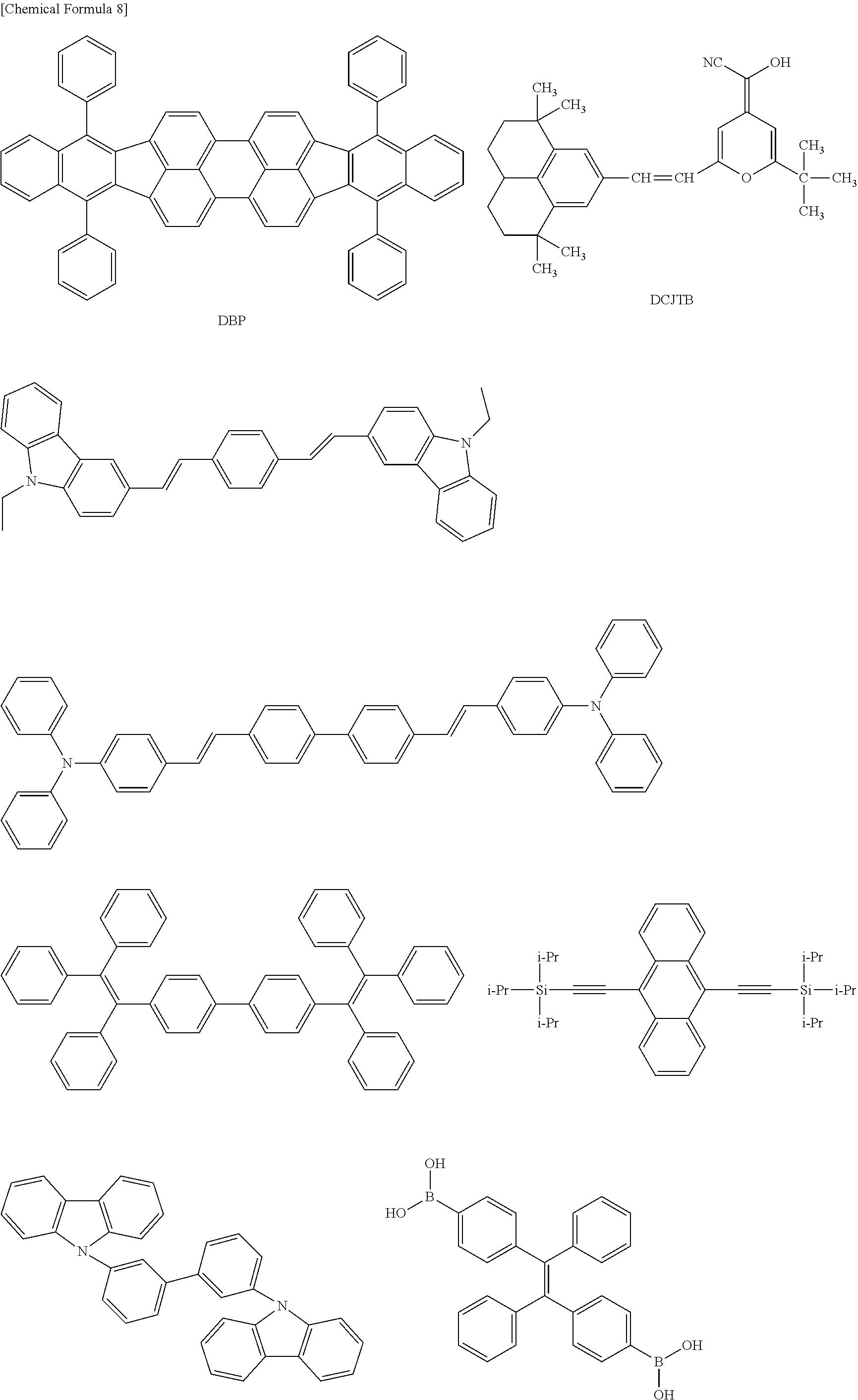

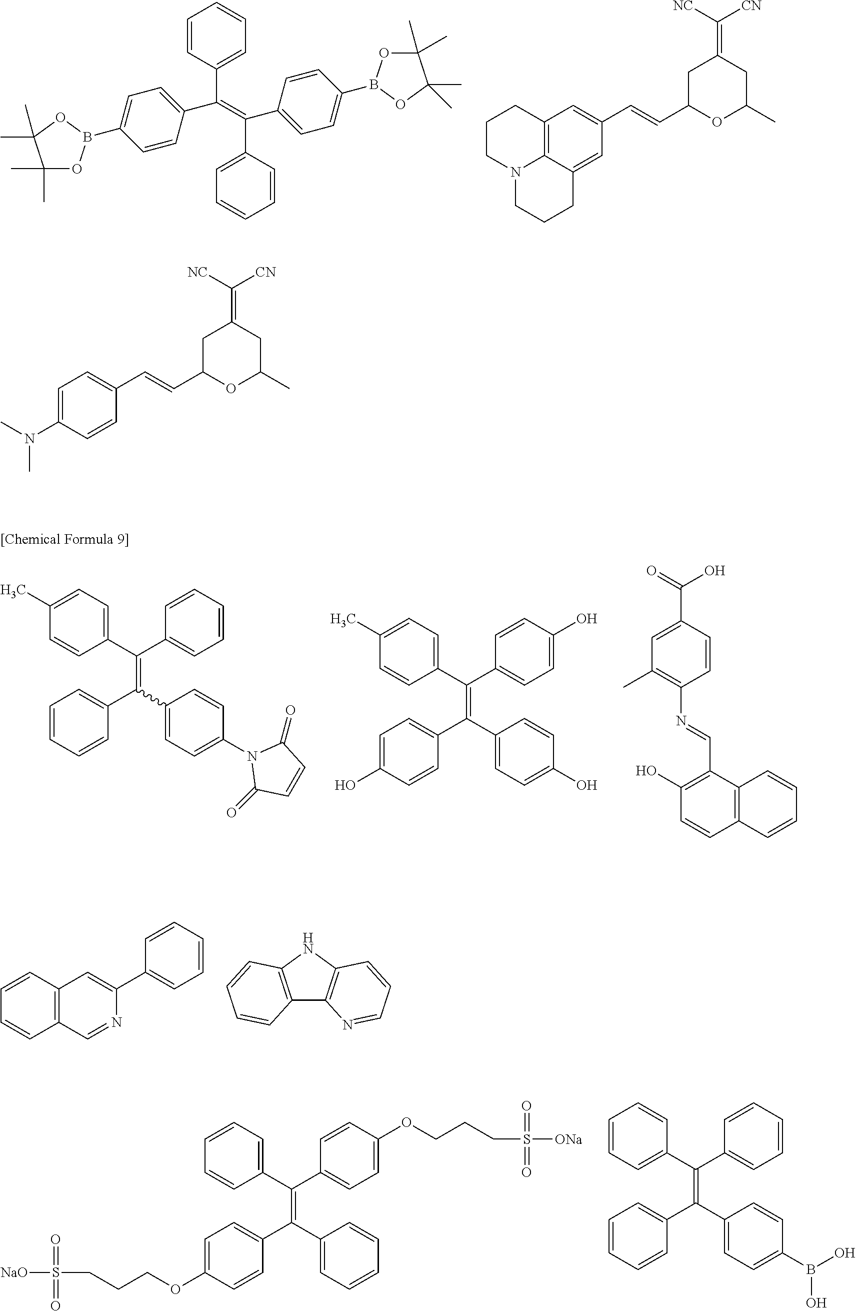

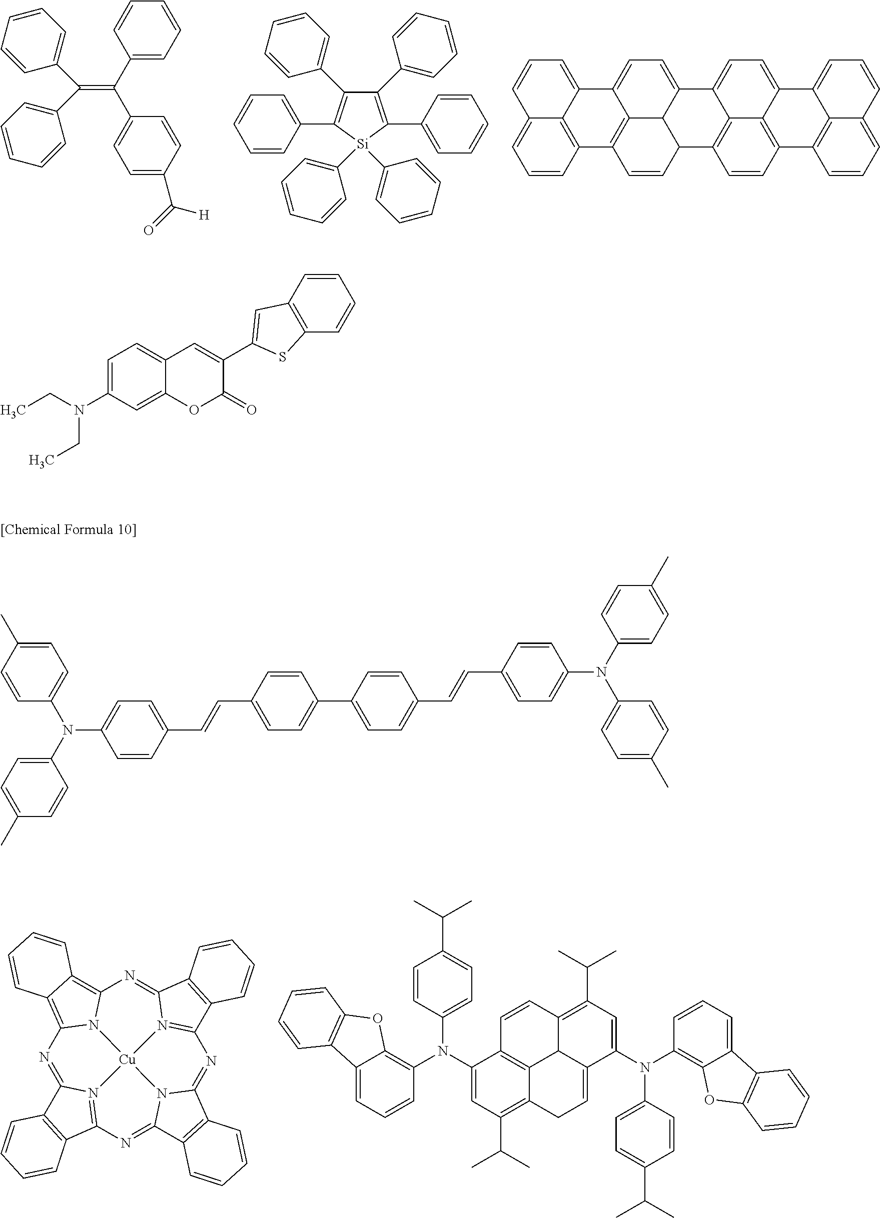

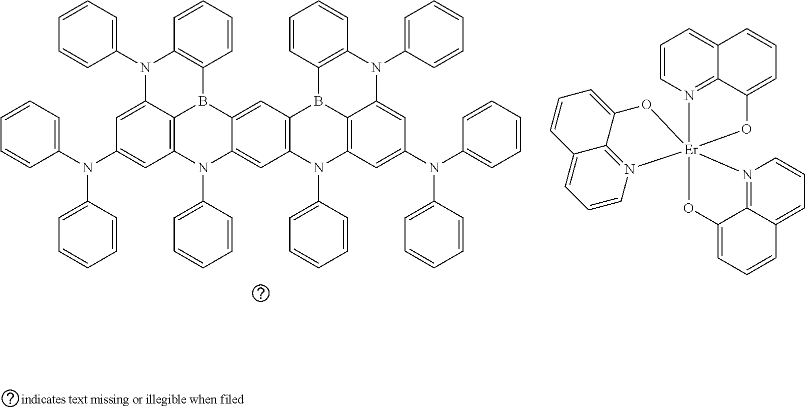

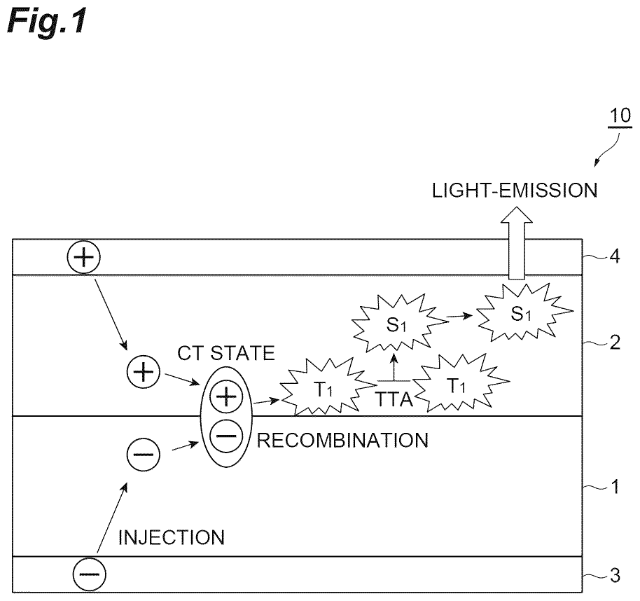

As illustrated in FIG. 1, the OLED device of this embodiment may be constituted by a pair of electrodes, the first organic semiconductor layer, and the second organic semiconductor layer, or may include other organic semiconductor layers, other inorganic compound layers, and the like which are known in the related art.

Examples of layers which may be provided between the pair of electrodes in the OLED device of this embodiment are a hole injection layer, an electron block layer, a hole transport layer, a light-emitting layer, an electron transport layer, a hole block layer, an electron injection layer, and the like in this order from a positive electrode. Among these, the first organic semiconductor layer may be the electron transport layer, and the second organic semiconductor layer may be the light-emitting layer.

Note that, functions of the layers are not strictly distinguished. For example, the light-emitting layer that is the second organic semiconductor layer may also function as the hole transport layer, or the hole block layer may also function as the electron injection layer.

The order of the respective layers in the OLED device is also not limited to the above-described configuration, and for example, the hole injection layer may be located between the electron block layer and the hole transport layer, and the electron injection layer may be located between the hole block layer and the electron transport layer.

In the respective layers of the OLED device, layers containing the same organic semiconductor material may exist. For example, in a case where the OLED device contains rubrene as the second organic semiconductor material in the second organic semiconductor layer (light-emitting layer), a hole block layer formed from rubrene may be provided.

The OLED device of this embodiment can be manufactured by forming the first and second organic semiconductor layers by a known method in the related art, for example, a method such as a vacuum evaporation method, a chemical vapor deposition method, a sputtering method, an evaporation and polymerization method, a spin coating method, a blade coating method, a bar coating method, a dip coating method, and a laminating method. Specifically, for example, the OLED device of this embodiment can be manufactured by stacking the first electrode, the first organic semiconductor layer, the second organic semiconductor layer, the second electrode, and any other layers on a substrate. A method of forming the respective organic semiconductor layers can be appropriately selected depending on compounds. As the substrate, for example, a glass substrate, a quartz substrate, a sapphire substrate, a plastic substrate, a film substrate, and the like can be employed.

The thickness of the first and second organic semiconductor layers in the OLED device of this embodiment is not particularly limited, but the thickness is preferably 0.1 nm to 500 nm, and more preferably 2 nm to 200 nm.

The OLED device is expected to be applied to, for example, an OLED display, an OLED illumination, a digital signage, a light source for a photosensor, a laser light source, a light source for optical communication, and the like.

### Examples

Hereinafter, the invention will be described in more detail with reference to Examples, but the invention is not limited to Examples at all. Note that, structures of compounds used in Examples are shown below.

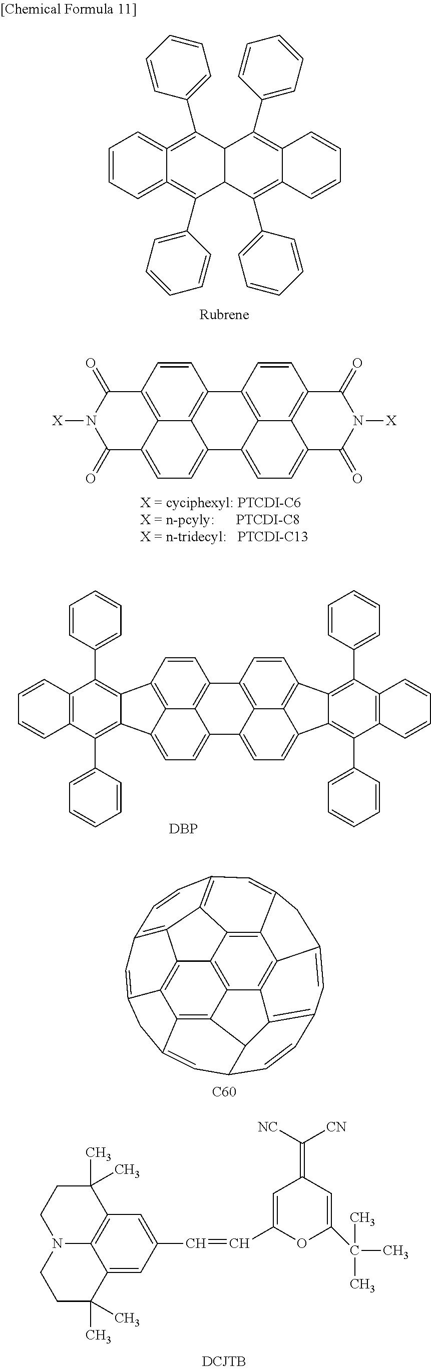

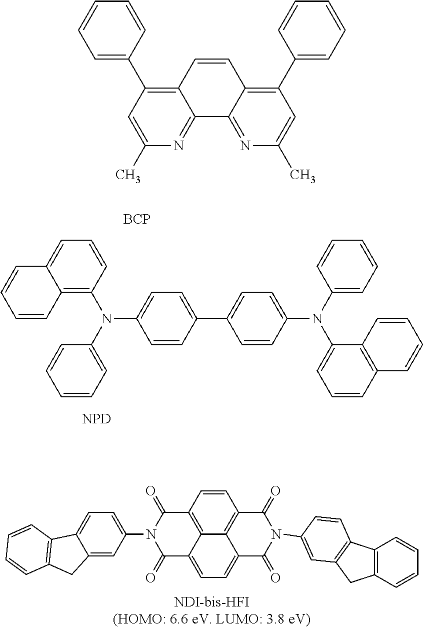

<Measurement of Absorption (ABS) Spectrum and Photoluminescence (PL) Spectrum>

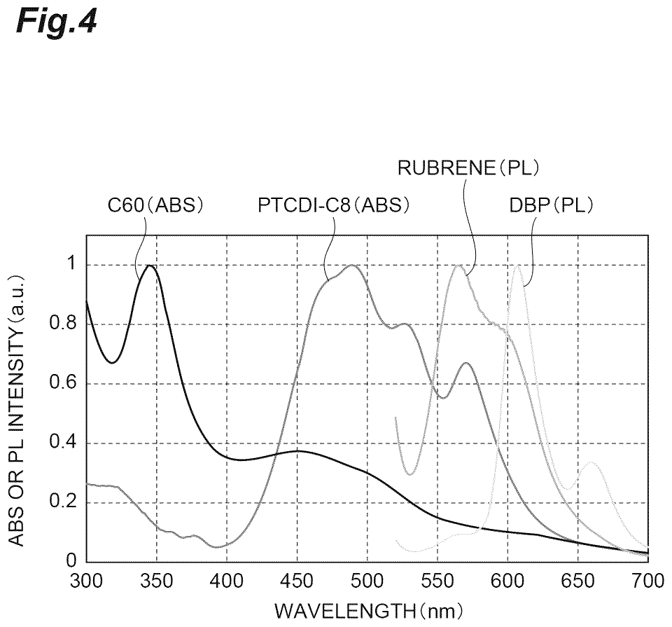

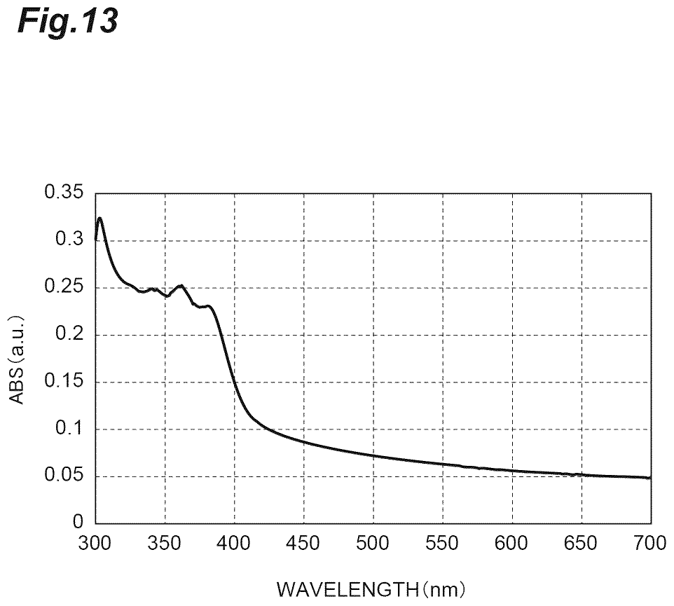

Rubrene, PTCDI-C8, C60, or DBP was thermally evaporated onto a quartz substrate in a high-vacuum state (about 10⁻⁵ Pa) in a vacuum evaporation system to form a single-layer thin film. The thickness of the layer was approximately 50 nm. A PL spectrum was measured with respect to thin films of rubrene and DBP, and an ABS spectrum was measured with respect to thin films of PTCDI-C8 and C60. Results thereof are shown in FIG. 4. In addition, results obtained by measuring the ABS spectrum with respect to NDI-bis-HFI are shown in FIG. 13.

The absorption spectrum was measured by a spectrometer (V-570, manufactured by JASCO Corporation).

The photoluminescence spectrum was measured by spectrofluorophotometer (Fluorolog, manufactured by HORIBA, Ltd.).

As is clear from FIG. 4, a peak wavelength (approximately 565 nm) of the PL spectrum of rubrene (second organic semiconductor material) is on a long wavelength side in comparison to a peak wavelength (approximately 490 nm and approximately 345 nm, respectively) of the ABS spectrum of PTCDI-C8 and C60 (first organic semiconductor material). In addition, a peak wavelength (approximately 605 nm) of the PL spectrum of DBP (third organic semiconductor material) is on a long wavelength side in comparison to the peak wavelength of the PL spectrum of rubrene. In addition, as illustrated in FIG. 13, a peak wavelength of the ABS spectrum of NDI-bis-HFI is approximately 305 nm, and is on a short wavelength side in comparison to the peak wavelength of the PL spectrum of rubrene.

<Measurement of PL Intensity>

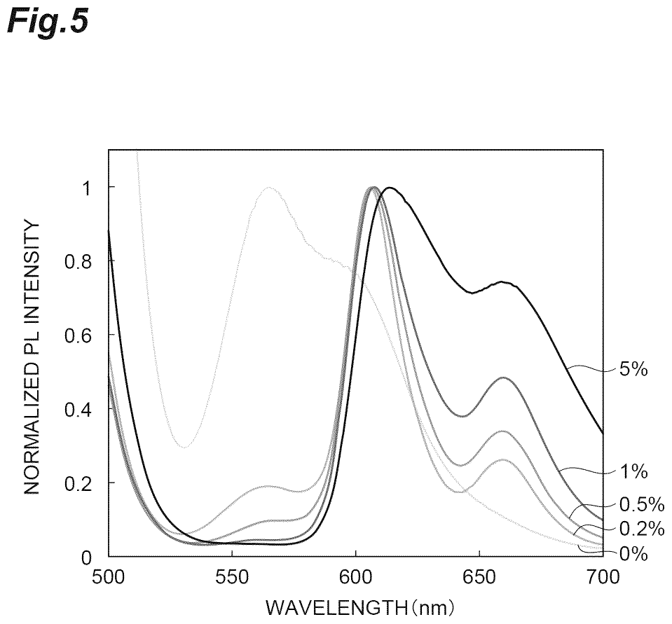

With regard to a single-layered rubrene layer, a sample without a dopant (0% by volume), and samples to which DBP as a dopant is added in an amount of 0.2% by volume, 0.5% by volume, 1% by volume, and 5% by volume, respectively, on the basis of the entirety of the rubrene layer were prepared, and a photoluminescence intensity (PL intensity) was measured with respect to each of the samples. The rubrene layer was formed through thermal evaporation on a quartz substrate at a high-vacuum state (about 10⁻⁵ Pa) in a vacuum evaporation system. DBP was introduced by a co-evaporation method when depositing the rubrene layer, and a mixing concentration was controlled by a ratio of evaporation rates. Measurement of the PL intensity was performed by an absolute PL quantum yield measuring device (Quantaurus-QY, manufactured by HAMAMATSU PHOTONICS K.K.). Results thereof are shown in FIG. 5. As is clear from FIG. 5, in a case of adding DBP as a dopant, light-emission was confirmed near approximately 605 nm derived from DBP, and energy transfer from rubrene to DBP could be confirmed.

<Measurement of Photoluminescence Quantum Yield (PL QY)>

With respect to various rubrene layers prepared in the measurement of the PL intensity, a photoluminescence quantum yield (PL QY) was measured by using an absolute PL quantum yield measuring device (Quantaurus-QY, manufactured by HAMAMATSU PHOTONICS K.K.). Results thereof are shown in Table 1.

TABLE 1

| 465 nm excitation | PL QY (%) |
|---|---|
| Non-doped | 29.1 |
| DBP: 0.2% by volume | 40.8 |
| DBP: 0.5% by volume | 72.6 |
| DBP: 1% by volume | 65.5 |
| DBP: 5% by volume | 62.4 |

As is clear from Table 1, in a case of adding the dopant (DBP), the photoluminescence quantum yield was higher in comparison to a case where the dopant was not added, and particularly, the highest photoluminescence quantum yield (72.6%) was obtained in a case where the amount of DBP added was 0.5% by volume.

### Example 1

An MoO₃ hole injection layer (10 nm, 0.01 nm/s), a rubrene layer (50 nm, 0.1 nm/s), a PTCDI-C8 layer (50 nm, 0.1 nm/s), an LiF electron injection layer (0.2 nm, 0.001 nm/s), and an Al electrode (70 nm, 0.3 nm/s) were thermally evaporated onto a glass substrate coated with indium tin oxide (ITO) (the thickness of ITO: 150 nm, a sheet resistance: 10.3 Ω/sq, manufactured by techno print co., ltd.) in this order in a high-vacuum state (about 10⁻⁵ Pa) in a vacuum evaporation system. The resultant device was sealed with a glass substrate and an epoxy resin in a glove box to obtain an OLED device. Note that, DBP as a dopant was added to the rubrene layer in an amount of 0.5% by volume on the basis of the entirety of the rubrene layer. DBP was introduced by a co-evaporation method when depositing the rubrene layer, and a mixing concentration was controlled by a ratio of evaporation rates.

The obtained OLED device has the following configuration.

ITO electrode/MoO₃ hole injection layer/rubrene layer (doped with DBP)/PTCDI-C8 layer/LiF electron injection layer/Al electrode

### Comparative Example 1

An OLED device was prepared in a similar manner as in Example 1 except that DBP was not added. The obtained OLED device has the following configuration.

ITO electrode/MoO₃ hole injection layer/rubrene layer (non-doped)/PTCDI-C8 layer/LiF electron injection layer/Al electrode

<Evaluation of OLED Device>

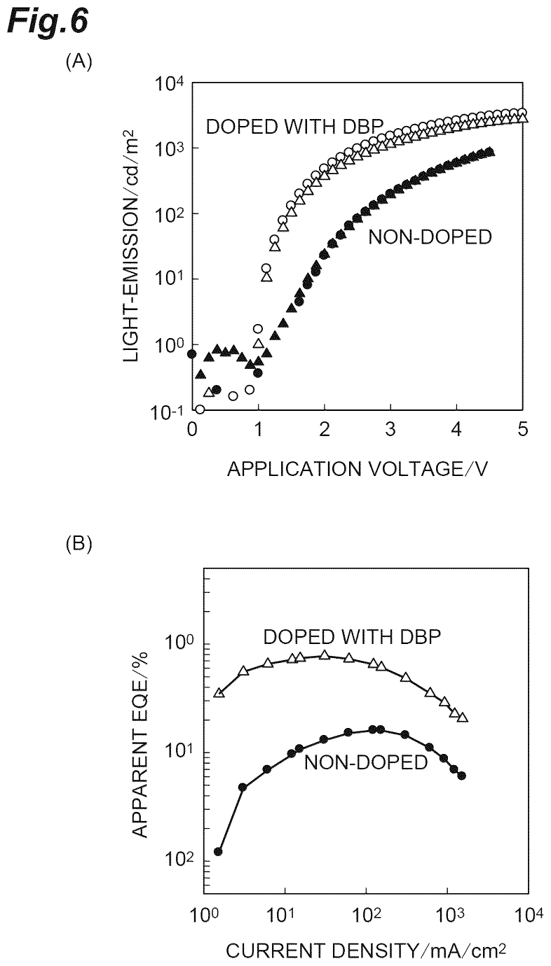

V-luminance characteristics of the OLED device of Example 1 and Comparative Example 1 were measured by using a source measure unit (B2902A, manufactured by Keysight Technologies) and a luminance meter (BM-9, manufactured by TOPCOM CORPORATION). Results thereof are shown in FIG. 6(A).

An external quantum yield (EQE) of the OLED devices of Example 1 and Comparative Example 1 was measured by using a corrected high-sensitivity/broadband spectrometer (AvaSpec-UV/VIS/NIR, manufactured by Avantes BV). Results thereof are shown in FIG. 6(B).

As is clear from FIGS. 6(A) and 6(B), in a case where a dopant is present (Example 1), light-emission luminance under the same voltage condition was improved by a maximum of 9.89 times, and the external quantum yield (EQE) under the same current density condition was improved by a maximum of 28.9 times and by a minimum of 3.19 times in comparison to a case where the dopant was absent (Comparative Example 1).

### Example 2: Insertion of Hole Block Layer

An organic El element was prepared in a similar manner as in Example 1 except that a BCP layer (10 nm, 0.05 nm/s) was formed between the PTCDI-C8 layer and the LiF electron injection layer through thermal evaporation. The OLED device has the following configuration.

ITO electrode/MoO₃ hole injection layer/rubrene layer (doped with DBP)/PTCDI-C8 layer/BCP layer/LiF electron injection layer/Al electrode

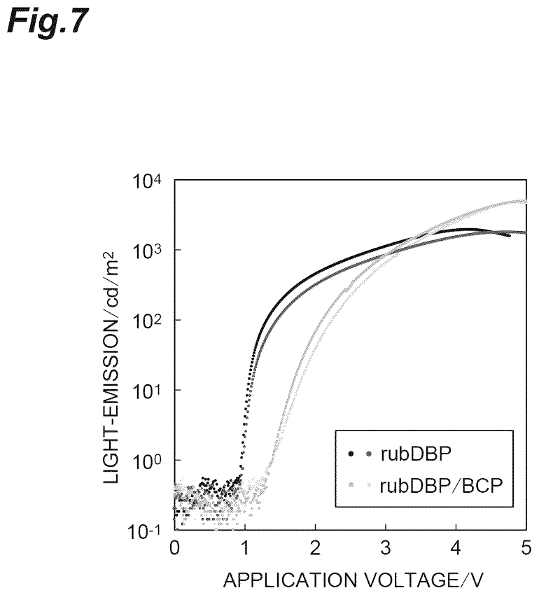

Results obtained by measuring V-luminance characteristics with respect to the obtained OLED device (rubDBP/BCP) by the above-described method are shown in FIG. 7 in combination with the measurement results of the OLED device (rubDBP) of Example 1. As is clear from FIG. 7, when the BCP layer is inserted, light-emission luminance at a high-voltage region is improved.

### Example 3: Insertion of Electron Block Layer

Two kinds of OLED devices were prepared in a similar manner as in Example 1 except that a rubrene layer (10 nm, 0.1 nm/s) (Example 3A) or an NPD layer (10 nm, 0.1 nm/s) (Example 3B) was formed between the MoO₃ hole injection layer and the rubrene layer (doped with DBP) through thermal evaporation. These OLED devices have the following configuration.

### Example 3A

ITO electrode/MoO₃ hole injection layer/rubrene layer (non-doped)/rubrene layer (doped with DBP)/PTCDI-C8 layer/LiF electron

### Example 3B

ITO electrode/MoO₃ hole injection layer/NPD layer/rubrene layer (doped with DBP)/PTCDI-C8 layer/LiF electron injection layer/Al electrode

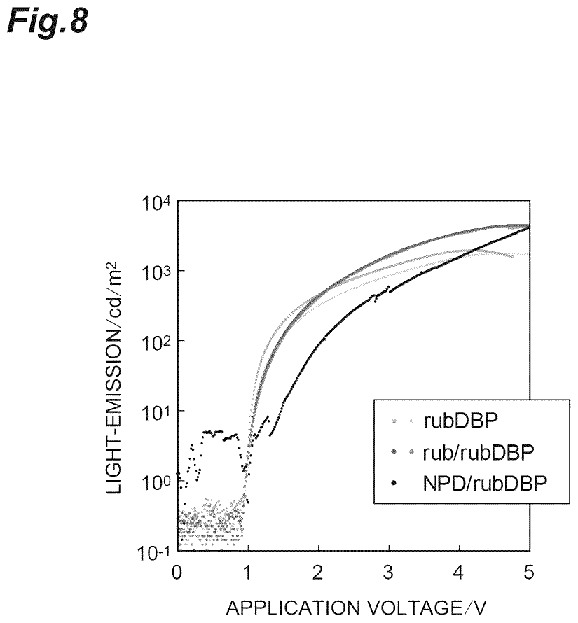

Results obtained by measuring V-luminance characteristics with respect to the two kinds of obtained OLED devices (rub/rubDBP, NPD/rubDPB) by the above-described method are shown in FIG. 8 in combination with the measurement results of the OLED device (rubDBP) of Example 1. As is clear from FIG. 8, light-emission luminance at a high-voltage region is improved when the rubrene layer or the NPD layer is inserted.

### Example 4: Examination of First Organic Semiconductor Layer

Three kinds of OLED devices were prepared in a similar manner as in Example 3A except that a PTCDI-C6 layer (50 nm, 0.1 nm/s) (Example 4A), a PTCDI-C13 layer (50 nm, 0.1 nm/s) (Example 4B), or a C60 layer (50 nm, 0.1 nm/s) (Example 4C) was formed instead of the PTCDI-C8 layer through thermal evaporation. These OLED devices have the following configurations.

### Example 4A

ITO electrode/MoO₃ hole injection layer/rubrene layer (non-doped)/rubrene layer (doped with DBP)/PTCDI-C6 layer/LiF electron injection layer/Al electrode

### Example 4B

ITO electrode/MoO₃ hole injection layer/rubrene layer (non-doped)/rubrene layer (doped with DBP)/PTCDI-C13 layer/LiF electron

### Example 4C

ITO electrode/MoO₃ hole injection layer/rubrene layer (non-doped)/rubrene layer (doped with DBP)/C60 layer/LiF electron injection layer/Al electrode

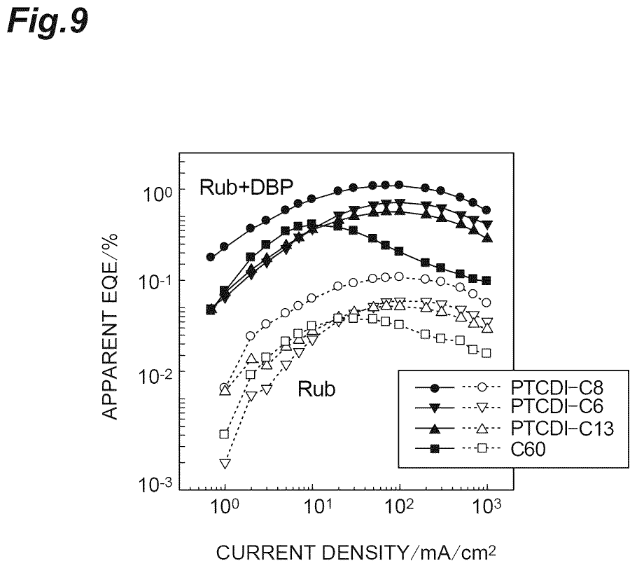

Results obtained by measuring the external quantum yield (EQE) with respect to the three kinds of obtained OLED devices by the above-described method are shown in FIG. 9 in combination with the measurement results of the OLED device of Example 3A. In addition, with respect to Examples 3A and 4A to 4C, OLED devices for comparison which use a rubrene layer (non-doped) having a thickness of 60 nm instead of the “rubrene layer (non-doped)/rubrene layer (doped with DBP)” were prepared, and measurement was performed in a similar manner. Results thereof are shown in FIG. 9. As is clear from FIG. 9, even in a case of employing any electron transport layer, when employing the rubrene layer (doped with DBP), light-emission efficiency was improved by approximately 10 times, but when using the PTCDI-C8 layer, the light-emission efficiency is the highest.

### Example 5: Examination of Dopant

An OLED device was prepared in a similar manner as in Example 3A except that DCJTB (0.5% by volume) was employed as the dopant instead of DBP with respect to the rubrene layer (doped with DBP). The OLED device has the following structure.

ITO electrode/MoO₃ hole injection layer/rubrene layer (non-doped)/rubrene layer (doped with DCJTB)/PTCDI-C8 layer/LiF electron injection layer/Al electrode

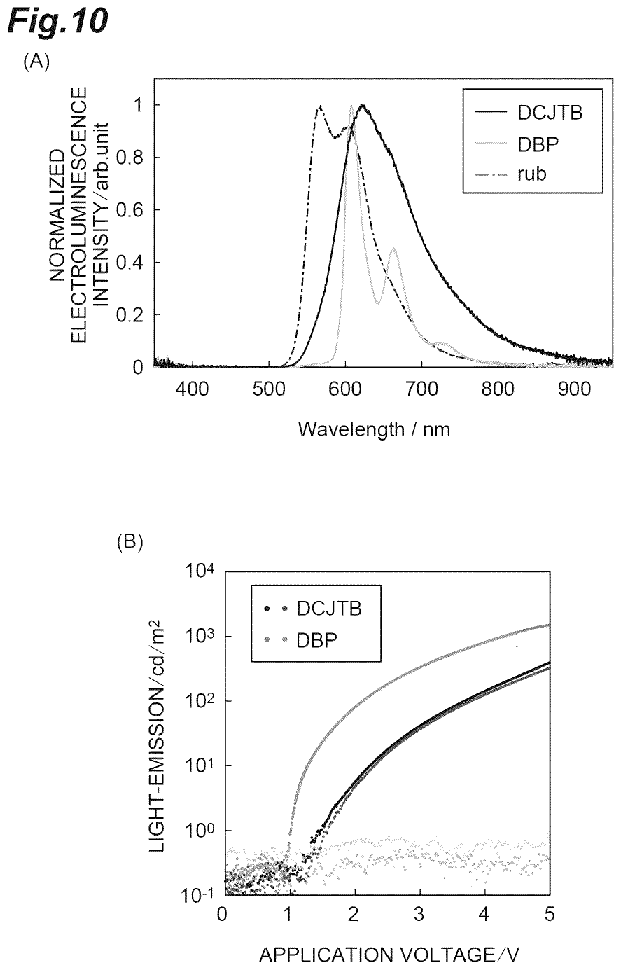

With respect to the obtained OLED device (DCJTB), results obtained by measuring an electroluminescence (EL) spectrum by using a high-sensitivity/broadband spectrometer (AvaSpec-UV/VIS/NIR, manufactured by Avantes) are shown in FIG. 10(A) in combination with the measurement results of the OLED device (DBP) of Example 3A and the measurement results of Comparative Example 1 (rub). As is clear from the results, in a case of using the dopant (DBP or DCJTB), energy transfer from rubrene to DBP or DCJTB occurred, and thus light-emission of rubrene was extinguished and light-emission derived from DBP or DCJTB was observed.

In addition, results obtained by measuring V-luminance characteristics with respect to the obtained OLED device (DCJTB) by the above-described method are shown in FIG. 10(B) in combination with the measurement results of the OLED device (DBP) of Example 3A. As is clear from FIG. 10(B), in a case of being doped with DBP, light-emission luminance is high.

### Example 6: Examination of Film Thickness of Electron Transport Layer

An OLED device was prepared in a similar manner as in Example 3A except that the thickness of PTCDI-C8 layer was changed from 50 nm to 20 nm.

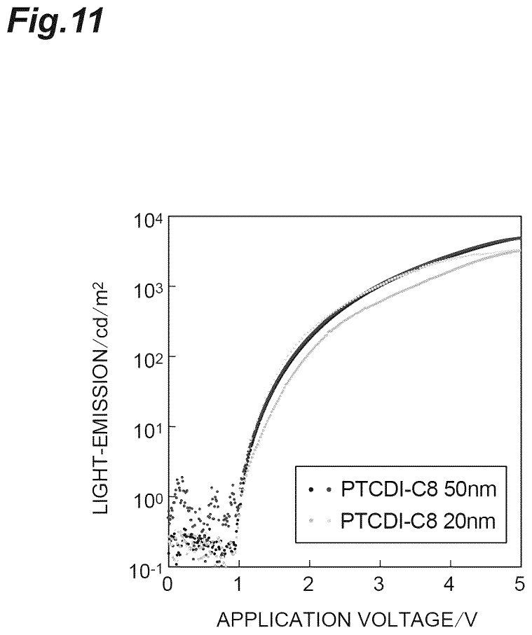

Results obtained by measuring V-luminance characteristics with respect to the obtained OLED device by the above-described method are shown in FIG. 11 in combination with the measurement results of the OLED device of Example 3A. As is clear from FIG. 11, even in a case of setting the film thickness to 20 nm, the light-emission luminance is high.

### Example 7: Examination of Film Thickness of Light-Emitting Layer

OLED devices were prepared in a similar manner as in Example 3A except that the thickness of the rubrene layer (doped with DBP) was changed from 50 nm to 20 nm, 100 nm, 150 nm, or 200 nm.

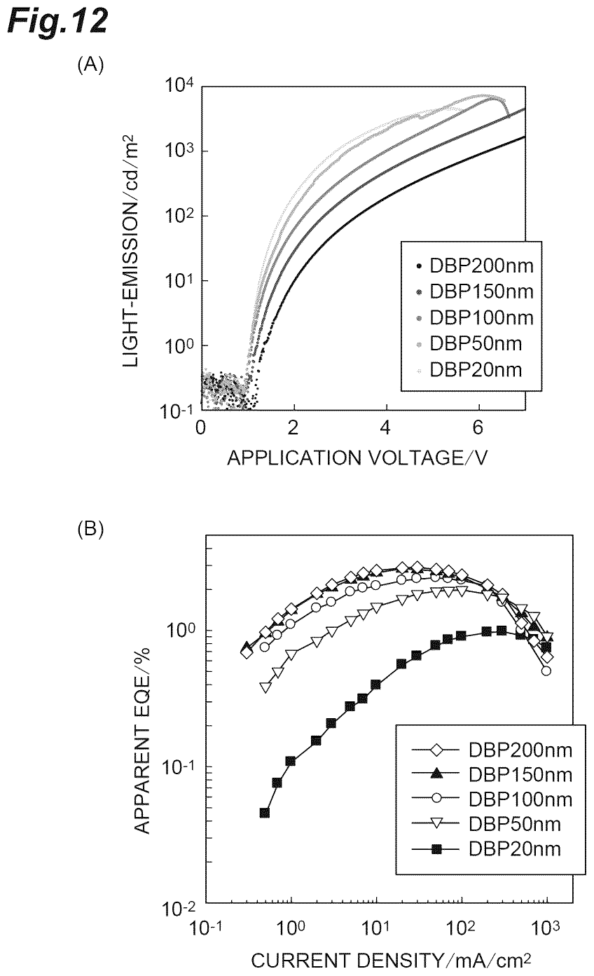

Results obtained by measuring V-luminance characteristics with respect to the obtained OLED devices by the above-described method are shown in FIG. 12(A) in combination with the measurement results of the OLED device of Example 3A, and results obtained by measuring the external quantum yield (EQE) are shown in FIG. 12(B) in combination with the measurement results of the OLED device of Example 3A. As is clear from FIG. 12(A), in any film thickness, the light-emission luminance is high. As is clear from FIG. 12(B), when film thickness is large (200 nm), EQE is large (a maximum of 2.91%@30 mA/cm 2).

### Example 8: Examination of First Organic Semiconductor Layer (Part 2)

An OLED device was prepared in a similar manner as in Example 3A except that an NDI-bis-HFI layer (50 nm) was formed instead of PTCDI-C8 layer through thermal evaporation. The OLED device has the following configuration.

ITO electrode/MoO₃ hole injection layer/rubrene layer (non-doped)/rubrene layer (doped with DBP)/NDI-bis-HFI layer/LiF electron injection layer/Al electrode

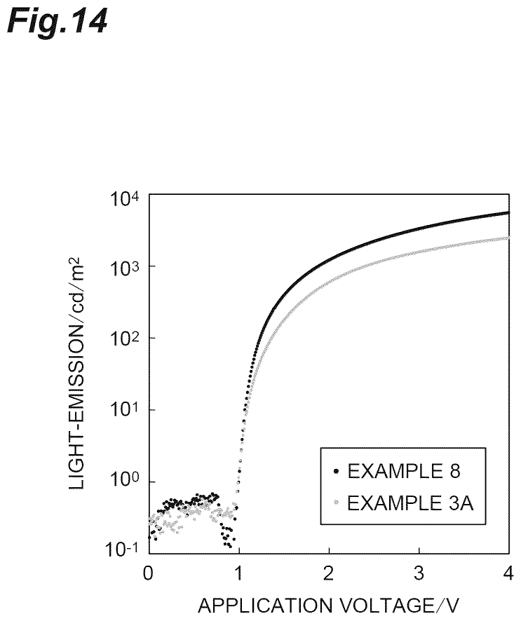

Results obtained by measuring V-luminance characteristics with respect to the obtained OLED device by the above-described method are shown in FIG. 14 in combination with the measurement results of the OLED device of Example 3A. As is clear from FIG. 14, the OLED device of Example 8 can accomplish high light-emission luminance (380 cd/m) even at low voltage (1.5 V).

### REFERENCE SIGNS LIST

1: first organic semiconductor layer, 2: second organic semiconductor layer, 3: first electrode, 4: second electrode, 10: OLED device.

1. An OLED (organic light-emitting diode) device comprising:
a plurality of organic semiconductor layers sandwiched between a pair of electrodes,
wherein the organic semiconductor layers include a first organic semiconductor layer containing a first organic semiconductor material, and a second organic semiconductor layer containing a second organic semiconductor material and a third organic semiconductor material,
the first organic semiconductor layer and the second organic semiconductor layer form a joining surface,
a HOMO (highest occupied molecular orbital) level of the first organic semiconductor material is lower than a HOMO level of the second organic semiconductor material, and a LUMO (lowest unoccupied molecular orbital) level of the first organic semiconductor material is lower than a LUMO level of the second organic semiconductor material,
the second organic semiconductor material is a material in which triplet-triplet annihilation is caused to occur,
an energy of a first triplet excited state (T₁) of the second organic semiconductor material is smaller than an energy difference between the HOMO level of the second organic semiconductor material and the LUMO level of the first organic semiconductor material,
the energy difference between the HOMO level of the second organic semiconductor material and the LUMO level of the first organic semiconductor material is smaller than an energy difference between the HOMO level and the LUMO level of the second organic semiconductor material by 0.5 eV or more,
in the second organic semiconductor layer, the second organic semiconductor material is a host material, and the third organic semiconductor material is a dopant, and
a peak wavelength of a photoluminescence spectrum of the second organic semiconductor material is on a long wavelength side in comparison to a peak wavelength of an absorption spectrum of the first organic semiconductor material.

2. The OLED device according to claim 1,
wherein a difference between the HOMO level of the first organic semiconductor material and the HOMO level of the second organic semiconductor material is 0.5 eV or more.

3. The OLED device according to claim 1,
wherein a difference between the LUMO level of the first organic semiconductor material and the LUMO level of the second organic semiconductor material is 0.5 eV or more.

4. The OLED device according to claim 1,
wherein a difference between the energy of the first excited triplet state (T₁) of the second organic semiconductor material and the energy difference between the HOMO level of the second organic semiconductor material and the LUMO level of the first organic semiconductor material is less than 0.8 eV.

5. The OLED device according to claim 2,
wherein a difference between the LUMO level of the first organic semiconductor material and the LUMO level of the second organic semiconductor material is 0.5 eV or more.

6. The OLED device according to claim 2,
wherein a difference between the energy of the first triplet excited state (T₁) of the second organic semiconductor material and the energy difference between the HOMO level of the second organic semiconductor material and the LUMO level of the first organic semiconductor material is less than 0.8 eV.

7. The OLED device according to claim 3,
wherein a difference between the energy of the first triplet excited state (T₁) of the second organic semiconductor material and the energy difference between the HOMO level of the second organic semiconductor material and the LUMO level of the first organic semiconductor material is less than 0.8 eV.

8. The OLED device according to claim 1,
wherein an energy difference between a HOMO level and a LUMO level in the third organic semiconductor material is smaller than an energy difference between a HOMO level and a LUMO level in the second organic semiconductor material and a peak wavelength of a photoluminescence spectrum of the third organic semiconductor material is on a long wavelength side in comparison to a peak wavelength of a photoluminescence spectrum of the second organic semiconductor material.
